(19) United States
(12) Patent Application Publication
(10) Pub. No.: US 2024/0170278 A1
(43) Pub. Date: May 23, 2024

(54) METHOD FOR PRODUCING SEMICONDUCTOR SUBSTRATE FOR MEMORY ELEMENTS

(71) Applicant: MITSUBISHI GAS CHEMICAL COMPANY, INC., Tokyo (JP)

(72) Inventors: Toshiyuki OIE, Taichung City (TW); Tomoyuki ADANIYA, Tokyo (JP)

(73) Assignee: MITSUBISHI GAS CHEMICAL COMPANY, INC., Tokyo (JP)

(21) Appl. No.: 18/283,083

(22) PCT Filed: Mar. 18, 2022
(86) PCT No.: PCT/JP2022/012521

§ 371 Date: Sep. 20, 2023

(30) Foreign Application Priority Data
Mar. 23, 2021 (JP) 2021-048721

(51) Int. Cl. H01L 21/02; H01L 21/306

(52) U.S. Cl. CPC H01L 21/02186; H01L 21/02233; H01L 21/02658; H01L 21/30604

(57) ABSTRACT

Provided is a method for producing a semiconductor substrate for high-performance memory elements with high production efficiency.

The method for producing a semiconductor substrate for memory elements, comprising a step (1) of bringing a semiconductor substrate including a titanium-containing film that includes at least one of titanium and a titanium alloy, a metallic tungsten film, and a tungsten oxide film into contact with a pretreatment agent to remove at least a part of the tungsten oxide film; and a step (2) of bringing the semiconductor substrate after being subjected to the step (1) into contact with an etching agent to remove at least a part of the titanium-containing film, wherein the pretreatment agent includes at least one tungsten oxide etchant that is selected from the group consisting of acids, ammonia, and ammonium salts.

### TECHNICAL FIELD

The present invention relates to a method for producing a semiconductor substrate for memory elements.

### BACKGROUND ART

In recent years, a further downsizing and advanced features have been required for memory elements, and technologies such as the miniaturization and three-dimensional integration of semiconductor substrates are developing.

For semiconductor substrates capable of such downsizing and advanced features of memory devices, metallic tungsten is suitably used as the material thereof. Metallic tungsten can be deposited by chemical vapor deposition (CVD), and has characteristics such as lower susceptibility to electromigration, low electrical resistance and high heat resistance. For this reason, metallic tungsten is used for embedded word lines or the like in memory elements such as DRAM.

The embedded word lines are known to be able to be fabricated by the following method, for example. That is, a silicon oxide film, a titanium-containing film (barrier film) that contains titanium or titanium alloys, and a metallic tungsten film are sequentially deposited on a silicon substrate having a recess formed by etching. Subsequently, the surface thereof is flattened by chemical mechanical polishing (CMP), and further the titanium-containing film and the metallic tungsten film, or the metallic tungsten film is selectively etched by dry etching or the like (CMP may be omitted). Thereafter, the titanium-containing film is selectively etched to fabricate embedded word lines in memory elements (Non Patent Literature 1).

In this manner, the method for producing a semiconductor substrate for memory elements includes a step of selectively removing titanium and/or a titanium alloy without damaging metallic tungsten (titanium and/or a titanium alloy selective etching step). For this reason, when metallic tungsten is used to produce small-sized and high-performance memory elements, there is a demand for an etching agent (with high Ti/W etching selectivity) configured to etch titanium and/or a titanium alloy without etching metallic tungsten.

### CITATION LIST

### Non Patent Literature

Non Patent Literature 1: SPCC 2019 Technical Program, “Wet Etchant for DRAM Word-line Titanium Nitride Recess with Selectivity to Tungsten”, Wilson et al., [https://www.linx-consulting.com/wp-content/uploads/2019/04/03-15-W_Yeh-Dupont-Wet_Etchant_for_DRAM_Word_line_TiN_Recess_with_Selectivity_to_W.pdf]

### SUMMARY OF INVENTION

### Technical Problem

However, it has been found that there are cases where memory elements having desired performance cannot be obtained by using conventional etching agents in an attempt to produce a semiconductor substrate for memory elements in which metallic tungsten is used as a material. One cause of this is thought to be due to an influence of a tungsten oxide film that is formed by oxidation of the surface of a metallic tungsten film in a process of producing a semiconductor substrate for memory elements. For instance, there are cases where titanium or a titanium alloy cannot be etched since the etching agent is not able to come in contact with titanium or a titanium alloy when the tungsten oxide film is present in a form of covering the surface of at least a part of the titanium-containing film in the embedded word lines.

Therefore, it is conceivable that tungsten oxide is removed by the aid of a pretreatment agent prior to the selective etching step of titanium nitride with the etching agent. During this occasion, when the removal rate of the tungsten oxide film with the pretreatment agent is slow, the time required for the pretreatment with the pretreatment agent becomes longer, and thus the production efficiency (throughput) of a semiconductor substrate for memory elements decreases. Therefore, it is preferable to use a pretreatment agent having a high removal rate of tungsten oxide. By using such a pretreatment agent, the tungsten oxide film can be rapidly removed, and then by carrying out the selective etching step of titanium and/or a titanium alloy with an etching agent, a semiconductor substrate for high-performance memory elements can be produced with high production efficiency.

That is, the present invention provides a method for producing a semiconductor substrate for high-performance memory elements with high production efficiency.

### Solution to Problem

The present inventors have conducted intensive studies with the aim of solving the above-mentioned problems. As a result, the present inventors have found that the above-mentioned problem can be solved by removing the tungsten oxide film with use of a specific pretreatment agent prior to a selective etching step of titanium and/or a titanium alloy with an etching agent, thereby having completed the present invention. That is, the present invention is as follows, for example.

[1] A method for producing a semiconductor substrate for memory elements comprising:

a step (1) of bringing a semiconductor substrate including a titanium-containing film that contains at least one of titanium and a titanium alloy, a metallic tungsten film, and a tungsten oxide film into contact with a pretreatment agent to remove at least a part of the tungsten oxide film; and

a step (2) of bringing the semiconductor substrate after being subjected to the step (1) into contact with an etching agent to remove at least a part of the titanium-containing film,

wherein the pretreatment agent includes at least one tungsten oxide etchant selected from the group consisting of acids, ammonia, and ammonium salts.

[2] The method for producing a semiconductor substrate for memory elements according to the above [1], wherein the pretreatment agent has a pH ranging from 0.1 to 13.

[3] The method for producing a semiconductor substrate for memory elements according to the above [1] or [2], wherein the tungsten oxide etchant contains at least one selected from the group consisting of hydrogen fluoride, hydrogen chloride, hydrogen bromide, hydrogen iodide, sulfuric acid, nitric acid, and phosphoric acid.

[4] The method for producing a semiconductor substrate for memory elements according to any of the above [1] to [3],

wherein the semiconductor substrate further includes a titanium oxide film, and

the step (1) further includes removing at least a part of the titanium oxide film.

[5] The method for producing a semiconductor substrate for memory elements according to any of the above [1] to [4],

wherein the etching agent contains an oxidizing agent (A), a fluorine compound (B), and a metallic tungsten corrosion inhibiter (C),

wherein an addition ratio of the oxidizing agent (A) is from 0.0001 to 10% by mass relative to a total mass of the etching agent;

an addition ratio of the fluorine compound (B) is from 0.005 to 10% by mass relative to a total mass of the etching agent; and

an addition ratio of the metallic tungsten corrosion inhibiter (C) is from 0.0001 to 5% by mass relative to a total mass of the etching agent.

[6] The method for producing a semiconductor substrate for memory elements according to the above [5], wherein the oxidizing agent (A) contains at least one selected from the group consisting of peroxy acids, halogen oxoacids, and salts thereof.

[7] The method for producing a semiconductor substrate for memory elements according to the above [5] or [6], wherein the fluorine compound (B) contains at least one selected from the group consisting of hydrogen fluoride (HF), tetrafluoroboric acid (HBF₄), hexafluorosilicic acid (H₂SiF₆), hexafluorozirconic acid (H₂ZrF₆), hexafluorotitanic acid (H₂TiF₆), hexafluorophosphoric acid (HPF₆), hexafluoroaluminic acid (H₂AlF₆), hexafluorogermanic acid (H₂GeF₆), and salts thereof.

[8] The method for producing a semiconductor substrate for memory elements according to any of the above [5] to [7], wherein the metallic tungsten corrosion inhibiter (C) includes at least one selected from the group consisting of ammonium salts represented by Formula (1) and heteroaryl salts having an alkyl group with 5 to 30 carbon atoms:

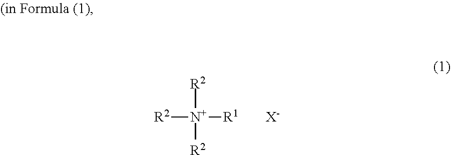

R¹ represents an alkyl group with 5 to 30 carbon atoms, a substituted or unsubstituted alkyl(poly)heteroalkylene group, a substituted or unsubstituted aryl(poly)heteroalkylene group, or a group represented by Formula (2):

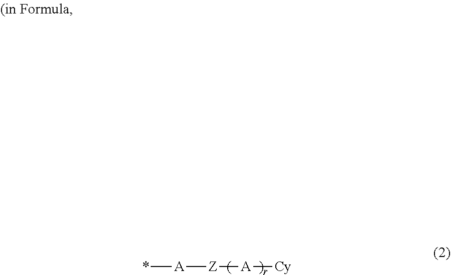

Cy is a substituted or unsubstituted cycloalkyl group with 3 to 10 carbon atoms, a substituted or unsubstituted heterocycloalkyl group with 2 to 10 carbon atoms, a substituted or unsubstituted aryl group with 6 to 15 carbon atoms, or a substituted or unsubstituted heteroaryl group with 2 to 15 carbon atoms,

each A independently represents an alkylene with 1 to 5 carbon atoms,

r is 0 or 1, and

Z is any of the following formulae:

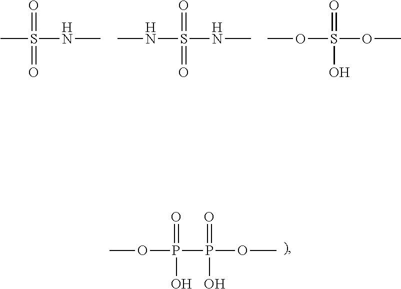

each R² independently represents a substituted or unsubstituted alkyl group with 1 to 18 carbon atoms, or a substituted or unsubstituted aryl group with 6 to 20 carbon atoms, and

X is a halide ion, a hydroxide ion, an organic sulfonate ion, tetrafluoroborate, or hexafluorophosphate).

### Advantageous Effects of Invention

According to the present invention, there is provided a method for producing a semiconductor substrate for high-performance memory elements with high production efficiency.

### BRIEF DESCRIPTION OF DRAWINGS

FIG. 1 is a schematic diagram of a step (1) according to the present invention.

### DESCRIPTION OF EMBODIMENTS

Hereinafter, the embodiments of the present invention will be described in detail.

### <Method for Producing a Semiconductor Substrate for Memory Elements>

A method for producing a semiconductor substrate for memory elements according to the present invention comprises a step (1) of bringing a semiconductor substrate including a titanium-containing film that contains at least one of titanium and a titanium alloy, a metallic tungsten film, and a tungsten oxide film into contact with a pretreatment agent to remove at least a part of the tungsten oxide film; and a step (2) of bringing the semiconductor substrate after being subjected to the step (1) into contact with an etching agent to remove at least a part of the titanium-containing film. In this configuration, the pretreatment agent contains at least one tungsten oxide etchant selected from the group consisting of acids, ammonia, and ammonium salts.

The pretreatment agent has a high etching rate of tungsten oxide that is formed on the surface of the material containing metallic tungsten included in the semiconductor substrate, and is capable of suitably removing tungsten oxide, and hence the throughput is not decreased. In addition, the etching rate of metallic tungsten during pretreatment is slow enough, and hence a semiconductor substrate for high-performance memory elements can be produced with high production efficiency.

Note that the titanium alloy is not particularly limited as long as it is obtained by adding one or more kinds of metal elements with the exception of titanium or one or more kinds of non-metal elements into titanium and has metallic properties, and examples thereof include alloys of titanium with at least one element selected from the group consisting of aluminum, nitrogen, carbon, molybdenum, vanadium, niobium, iron, chromium, nickel, tin, hafnium, zirconium, palladium, ruthenium, and platinum. Among them, titanium nitride is preferable. Note that, the term “titanium alloy” as used herein means an alloy whose titanium element content is 20% by atomic weight or more relative to the total atomic weight of the titanium alloy. Note that, the titanium element content in the titanium alloy is preferably 20% by atomic weight or more, more preferably 30% by atomic weight, still more preferably 35% by atomic weight, and particularly preferably from 40 to 99.9% by atomic weight relative to the total atomic weight of the titanium alloy.

The term “tungsten oxide” as used herein refers to a substance that is formed by oxidizing metallic tungsten, and usually means tungsten(VI) oxide (WO₃).

Hereinafter, the present invention will be described with reference to the drawing. Note that the drawing may be illustrated in an exaggerated manner for the sake of explanation, and may be in dimensions different from actual dimensions.

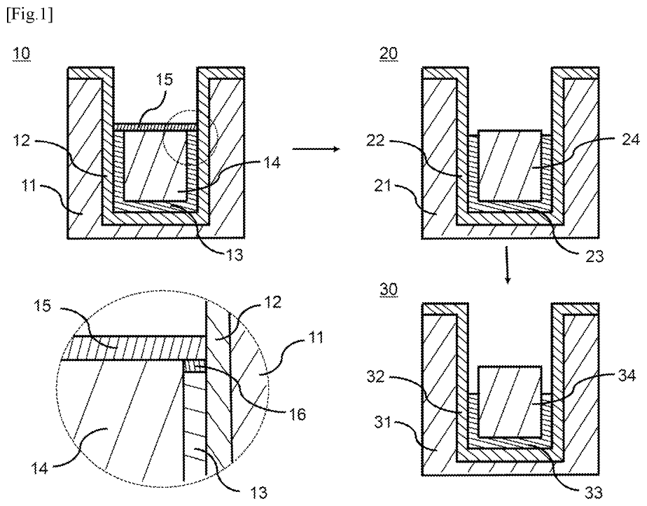

FIG. 1 is a schematic diagram of the step (1) according to the present invention. A semiconductor substrate (before being subjected to the step (1)) 10 includes a silicon substrate 11 having a recess, an insulating film 12 made of silicon oxide, a barrier film 13 made of titanium nitride, and a metallic tungsten film 14. Such semiconductor substrate (before being subjected to the step (1)) 10 can be produced by sequentially depositing an insulating film made of silicon oxide, a barrier film made of titanium nitride, and a metallic tungsten film on a silicon substrate having a recess, followed by planarization by chemical mechanical polishing (CMP), and selective etching of the barrier film and the metallic tungsten film by dry etching or the like (CMP may be omitted). Here, the semiconductor substrate (before being subjected to cleaning) 10 includes a tungsten oxide film 15, which is formed by oxidation of metallic tungsten, on the barrier film 13 and the metallic tungsten film 14. The tungsten oxide film 15 is present in a form of covering the surface of the barrier film 13, and hence there are cases where an etching agent cannot suitably come in contact with the barrier film 13 and is not able to etch the barrier film 13, in an attempt to selectively etch the barrier film 13 made of titanium nitride. Here, please refer to an enlarged view in FIG. 1, which illustrates a titanium oxide film 16 that is formed on the surface of the barrier film 13 made of titanium nitride. The titanium oxide film 16 may be formed by oxidization of titanium nitride on the surface of the barrier film 13 by oxygen that has passed through the tungsten film 15 since the tungsten oxide film 15 has a low film packing density. Apart from this, the titanium oxide film 16 may be formed by oxidization of titanium nitride in an ashing process which is optionally performed in a process of producing a semiconductor substrate for memory elements.

A pretreatment agent is applied to the semiconductor substrate (before being subjected to cleaning) 10 having such configuration, thereby enabling to remove the tungsten oxide film 15. In this configuration, the pretreatment agent has a high etching rate of tungsten oxide, and thus the throughput is not decreased and a high production efficiency can be achieved. In addition, the etching of metallic tungsten during pretreatment can be prevented or suppressed. As a result, a semiconductor substrate (after being subjected to the step (1)) 20 obtained through the pretreatment has a configuration in which a silicon substrate 21 having a recess, an insulating film 22 made of silicon oxide, a barrier film 23 made of titanium nitride, and a metallic tungsten film 24 are stacked in layers. For this reason, when the etching agent is applied in the step (2), the etching agent can suitably come into contact with the barrier film 23. As a result, titanium nitride can be selectively etched, and thus obtained semiconductor substrate (after being subjected to step (2)) 30 has a configuration in which a silicon substrate 31 having a recess, an insulating film 32, an etched barrier film 33, and a metallic tungsten film 34 are stacked in layers.

Note that, in one preferred embodiment, the pretreatment agent does not cause or hardly causes galvanic corrosion (dissimilar metal corrosion). In a case where titanium and/or a titanium alloy comes in contact with metallic tungsten, galvanic corrosion is liable to occur in metallic tungsten which has a relatively low natural potential compared to titanium and/or a titanium alloy depending on the processing environment. However, in one preferred embodiment of the present invention, the galvanic corrosion can be prevented or suppressed by using a suitable pretreatment agent.

In one preferred embodiment, the pretreatment agent can also remove at least a part of the titanium oxide film 16 along with the tungsten oxide film 15. As a result, the etching agent can more effectively come in contact with titanium and/or a titanium alloy. Consequently, titanium and/or a titanium alloy can be further selectively etched, and a high-performance semiconductor substrate can be produced.

Hereinafter, each step will be described in detail.

[Step (1)]

The step (1) is a step of bringing a semiconductor substrate including a titanium-containing film that contains at least one of titanium and a titanium alloy, a metallic tungsten film, and a tungsten oxide film into contact with a pretreatment agent to remove at least a part of the tungsten oxide film.

### (Semiconductor Substrate)

The semiconductor substrate includes: a titanium-containing film that contains at least one of titanium and a titanium alloy; a metallic tungsten film; and a tungsten oxide film. The configuration of the semiconductor substrate is not particularly limited, and a known configuration can be adopted as appropriate.

For example, when used for embedded word lines in memory elements, the semiconductor substrate may have a multilayer structure in which an insulating film, a barrier film made of titanium and/or a titanium alloy, and a metallic tungsten film are stacked in this order on a silicon substrate having a recess. In this configuration, the barrier film and the metallic tungsten film are usually disposed adjacent to each other.

The semiconductor substrate further includes a tungsten oxide film that is generated by oxidation of metallic tungsten on the surface of the metallic tungsten film. The shape of the tungsten oxide film is not particularly limited. For example, the tungsten oxide may form a film with uniform thickness, or may form a film with uneven thickness. Moreover, the tungsten oxide film may be one continuous film, or may present as a plurality of discontinuous films. Note that, the tungsten oxide film may be present on the surface of a film (such as a barrier film) adjacent to the metallic tungsten film since the volume of tungsten oxide increases in accordance with the oxidation of metallic tungsten. Note that, the tungsten oxide film is suitably removed with the pretreatment agent in the step (1).

The semiconductor substrate may further include a titanium oxide film that is generated by oxidation of titanium or a titanium alloy on the surface of the titanium-containing film. The said titanium oxide film can be formed by natural oxidation of titanium or a titanium alloy on the surface of the titanium-containing film. In this occasion, even if the surface of the titanium-containing film is covered with the tungsten oxide film, oxygen can pass through the tungsten oxide film when the tungsten oxide film has a low film packing density, and hence the natural oxidation of the surface of the titanium-containing film may take place. In addition, the titanium oxide film is also formed by reactions such as the oxidation of titanium or titanium alloys in an ashing process which is optionally performed in the process of producing a semiconductor substrate for memory elements. The shape of the titanium oxide film is not particularly limited. For example, the tungsten oxide may form a film with uniform thickness, or may form a film with uneven thickness. Moreover, the tungsten oxide film may be one continuous film, or may present as a plurality of discontinuous films. The titanium oxide film is preferably removed by a pretreatment agent in the step (1). In other words, in one preferred embodiment, the semiconductor substrate further includes a titanium oxide film, and the step (1) preferably further includes removing at least a part of the titanium oxide film. Note that the term “titanium oxide” as used herein refers to a chemical compound formed by the oxidization of titanium nitride, and usually means titanium(IV) oxide (TiO₂), titanium oxynitride (TiOₓN_{y}) (where x is from 0.01 to 2, and y is from 0 to 1), or a combination thereof

### (Pretreatment Agent)

The pretreatment agent includes a tungsten oxide etchant. By using the pretreatment agent, at least a part of the tungsten oxide film can be removed. Therefore, the pretreatment agent can be said to be a treatment agent for tungsten oxide film removal.

### Tungsten Oxide Etchant

The tungsten oxide etchant includes at least one selected from the group consisting of acids, ammonia, and ammonium salts.

The acid is not particularly limited, but examples thereof include: inorganic acids such as hydrogen fluoride, hydrogen chloride, hydrogen bromide, hydrogen iodide, sulfuric acid, nitric acid, and phosphoric acid; and organic acids such as acetic acid, methanesulfonic acid, trifluoromethanesulfonic acid, benzenesulfonic acid, p-toluenesulfonic acid, and 10-camphorsulfonic acid.

The ammonium salt is not particularly limited, but examples thereof include: ammonium fluoride (NH₄F); ammonium hydrogen fluoride (NH₄F·HF); tetraalkylammonium hydroxides such as tetraethylammonium hydroxide (TEAH), tetramethylammonium hydroxide (TMAH), ethyltrimethylammonium hydroxide, diethyldimethylammonium hydroxide, triethylmethylammonium hydroxide, tetrapropylammonium hydroxide, and tetrabutylammonium hydroxide; aryl group-containing ammonium hydroxides such as benzyltrimethylammonium hydroxide and benzyltriethylammonium hydroxide; and hydroxy group-containing ammonium hydroxides such as trimethyl(2-hydroxyethyl)ammonium hydroxide, triethyl(2-hydroxyethyl)ammonium hydroxide, tripropyl(2-hydroxyethyl)ammonium hydroxide, and trimethyl(1-hydroxypropyl)ammonium hydroxide.

Among the above, from the perspective of being able to prevent or suppress galvanic corrosion, the tungsten oxide etchant is preferably an acid, ammonium fluoride, or ammonium hydrogen fluoride, more preferably an inorganic acid, still more preferably hydrogen fluoride, hydrogen chloride, hydrogen bromide, hydrogen iodide, sulfuric acid, nitric acid, or phosphoric acid, particularly preferably hydrogen fluoride, hydrogen chloride, hydrogen bromide, hydrogen iodide, sulfuric acid, or nitric acid, and from the perspective of being able to suitably remove titanium oxide, the tungsten oxide etchant is most preferably hydrogen fluoride.

The above-mentioned tungsten oxide etchant may be used singly, or two or more kinds thereof may be used in combination. In other words, in one embodiment, from the perspective of being able to prevent or suppress galvanic corrosion, the tungsten oxide etchant preferably contains at least one selected from the group consisting of acids, ammonium fluoride, and ammonium hydrogen fluoride, more preferably contains at least one of inorganic acids, still more preferably contains at least one selected from the group consisting of hydrogen fluoride, hydrogen chloride, hydrogen bromide, hydrogen iodide, sulfuric acid, nitric acid, and phosphoric acid, particularly preferably contains at least one selected from the group consisting of hydrogen fluoride, hydrogen chloride, hydrogen bromide, hydrogen iodide, sulfuric acid, and nitric acid, and from the perspective of being able to suitably remove titanium oxide, the tungsten oxide etchant most preferably contains hydrogen fluoride.

The content of the tungsten oxide etchant is preferably from 0.001 to 50% by mass, more preferably from 0.01 to 10% by mass, still more preferably from 0.03 to 3% by mass, and particularly preferably from 0.05 to 1% by mass, relative to the total mass of the pretreatment agent. The content of the tungsten oxide etchant being 0.001% by mass or more is preferable since the etching rate of tungsten oxide is increased. On the other hand, the content of the tungsten oxide etchant being 50% by mass or less is preferable since the etching of metallic tungsten can be prevented or suppressed in the step (1).

### Solvent

The pretreatment agent preferably contains a solvent. The solvent has functions such as uniformly dispersing and diluting each component contained in the pretreatment agent.

Examples of the solvent include water and organic solvents.

The water mentioned above is not particularly limited, but is preferably water from which metal ions, organic impurities, particles and grains, and the like have been removed by distillation, ion exchange process, filtering process, various adsorption processes, or the like, more preferably pure water, and particularly preferably ultrapure water.

The organic solvent is not particularly limited, but examples thereof include: alcohols such as methanol, ethanol, 1-propanol, 2-propanol, 1-butanol, and tert-butanol; polyhydric alcohols such as ethylene glycol, propylene glycol, neopentyl glycol, 1,2-hexanediol, 1,6-hexanediol, 2-ethylhexane-1,3-diol, and glycerin; glycol ethers such as diethylene glycol monomethyl ether, diethylene glycol monoethyl ether, diethylene glycol monobutyl ether, propylene glycol monomethyl ether, propylene glycol monoethyl ether, dipropylene glycol monomethyl ether, tripropylene glycol monomethyl ether, dipropylene glycol dimethyl ether, dipropylene glycol monoethyl ether, propylene glycol n-propyl ether, dipropylene glycol n-propyl ether, tripropylene glycol n-propyl ether, propylene glycol n-butyl ether, dipropylene glycol n-butyl ether, tripropylene glycol n-butyl ether, and propylene glycol phenyl ether.

Among the above, the solvent is more preferably water. Note that, the solvent may be used singly, or two or more kinds thereof may be used in combination.

The addition ratio of the solvent, especially of water, is preferably 50% by mass or more, more preferably 80% by mass or more, still more preferably 90% by mass or more, and particularly preferably 95% by mass or more, relative to the total mass of the pretreatment agent.

### Additive

The pretreatment agent may further include an additive. The additive is not particularly limited, and examples thereof include pH adjusting agents such as lithium hydroxide, sodium hydroxide, potassium hydroxide, rubidium hydroxide, cesium hydroxide, beryllium hydroxide, magnesium hydroxide, calcium hydroxide, strontium hydroxide, and barium hydroxide. The additive may be used singly, or two or more kinds thereof may be used in combination.

### Physical Properties of the Pretreatment Agent

The pretreatment agent preferably has a pH ranging from 0.1 to 13, and from the perspective of being able to prevent or suppress galvanic corrosion, it is more preferably from 0.5 to 10, still more preferably from 0.5 to 5, and particularly preferably from 0.4 to 2.5.

The etching rate of tungsten oxide with the pretreatment agent is preferably 15 Å/min or more, more preferably from 20 to 500 Å/min, still more preferably from 20 to 100 Å/min, and particularly preferably from 20 to 50 Å/min. The etching rate of tungsten oxide with the pretreatment agent being 15 Å/min or more is preferable since the throughput is not decreased and the etching of metallic tungsten during pretreatment can be prevented. Note that the etching rate of tungsten oxide with the pretreatment agent means a value measured by the method used in Examples.

The etching rate of the metallic tungsten with the pretreatment agent is preferably 10 Å/min or less, more preferably 7.5 Å/min or less, still more preferably 5.0 Å/min or less, particularly preferably 3.0 Å/min or less, and most preferably from 0.1 to 2.8 Å/min. The etching rate of the metallic tungsten with the pretreatment agent being 10 Å/min or less is preferable since the etching of metallic tungsten in the step (1) (during pretreatment) can be prevented. Note that the etching rate of metallic tungsten with the pretreatment agent means a value measured by the method used in Examples.

The etching rate of titanium or titanium alloys with the pretreatment agent is preferably 10 Å/min or less, more preferably 6 Å/min or less, and still more preferably 2 Å/min or less. The etching rate of titanium or titanium alloys with the pretreatment agent being 10 Å/min or less is preferable since the etching in the step (2) described later can be suitably performed. Note that the etching rate of titanium or titanium alloys with the pretreatment agent means a value measured by the method used in Examples.

The etching rate of the insulating layer material with the pretreatment agent is preferably 3.0 Å/min or less, more preferably 1.0 Å/min or less, still more preferably 0.3 Å/min or less, particularly preferably 0.2 Å/min or less, and most preferably 0.1 Å/min or less. The etching rate of the insulating layer material with the pretreatment agent being 3.0 Å/min or less is preferable since the semiconductor substrate retains its shape and is enhanced in performance as a semiconductor element. Note that, the insulating layer material is not particularly limited, and examples thereof include silicon oxide (e.g., th-Ox). In addition, the etching rate of the insulating layer material with the pretreatment agent means a value measured by the method used in Examples.

The WO₃/W etching selectivity with the pretreatment agent is preferably 5 or more, more preferably from 10 to 100, still more preferably from 15 to 100, particularly preferably from 30 to 100, and most preferably from 50 to 90. The WO₃/W etching selectivity being 5 or more is preferable since a semiconductor substrate for high-performance memory elements can be produced. Note that, the term “WO₃/W etching selectivity” as used herein means the etching selectivity of tungsten oxide over metallic tungsten, and specifically means the ratio of the etching rate of tungsten oxide to the etching rate of metallic tungsten (the etching rate of tungsten oxide divided by the etching rate of metallic tungsten).

The corrosion potential of metallic tungsten (W) with the pretreatment agent is preferably from −1000 to −50 mV, more preferably from −500 to −50 mV, still more preferably from −300 to −50 mV, particularly preferably from −150 to −60 mV, and most preferably from −115 to −70 mV. Note that, the corrosion potential of metallic tungsten (W) with the pretreatment agent means a value measured by the method used in Examples.

The corrosion potential of titanium or a titanium alloy with the pretreatment agent is preferably from −500 to −20 mV, more preferably from −350 to −20 mV, still more preferably from −200 to −20 mV, particularly preferably from −130 to −30 mV, and most preferably from −100 to −40 mV. Note that the corrosion potential of titanium or a titanium alloy with the pretreatment agent means a value measured by the method used in Examples.

The corrosion potential difference between metallic tungsten (W) and titanium and/or a titanium alloy with the pretreatment agent (the difference of the corrosion potential of metallic tungsten (W) minus the corrosion potential of titanium and/or a titanium alloy) is not particularly limited, and is preferably from −50 to 300 my, more preferably from −50 to 200 mV, still more preferably from −30 to 100 mV, particularly preferably from −30 to 50 mV, and most preferably from −10 to 40 mV. The corrosion potential difference being within the above range is preferable since the occurrence of the galvanic corrosion of metallic tungsten (W) can be prevented or suppressed.

### (Contact)

The method of bringing the semiconductor substrate into contact with the pretreatment agent is not particularly limited, and a known technique can be appropriately adopted. Specifically, the semiconductor substrate may be immersed in the pretreatment agent, the pretreatment agent may be sprayed onto the semiconductor substrate, or the pretreatment agent may be dropped onto the semiconductor substrate (single wafer spin processing etc.). In this occasion, the immersion may be repeated two or more times, the spraying may be repeated two or more times, the dropping may be repeated two or more times, or the immersion, the spraying, and the dropping may be combined.

The contact temperature is not particularly limited, but is preferably from 0 to 90° C., more preferably from 15 to 80° C., and still more preferably from 20 to 70° C.

The contact time is not particularly limited, but is preferably from 10 seconds to 3 hours, more preferably from 10 seconds to 1 hour, still more preferably from 10 seconds to 45 minutes, and particularly preferably from 20 seconds to 5 minutes.

By bringing the semiconductor substrate into contact with the pretreatment agent, at least a part of the tungsten oxide film can be removed.

[Step (2)]

The step (2) is a step of bringing the semiconductor substrate after being subjected to the step (1) into contact with an etching agent thereby removing at least a part of the titanium-containing film.

### (Semiconductor Substrate After Being Subjected to the Step (1))

The semiconductor substrate after being subjected to the step (1) includes the titanium-containing film and the metallic tungsten film. All of the tungsten oxide film is preferably removed in the step (1), but a part of the tungsten oxide film may remain. In a case where the semiconductor substrate before being subjected to the step (1) includes a titanium oxide film, all of the titanium oxide film is preferably removed in the step (1), but a part of or all of the titanium oxide film may remain. By performing the step (1), at least a part of the tungsten oxide film is removed from the semiconductor substrate after being subjected to the step (1), so that the titanium-containing film can be suitably brought into contact with an etching agent in the step (2), and selective etching of titanium and/or a titanium alloy can be suitably performed.

### (Etching Agent)

The etching agent is not particularly limited, and a known etching agent can be used as long as it etches titanium and/or a titanium alloy but slowly etches metallic tungsten (i.e., it has a high Ti/W etching selectivity). Among them, the etching agent preferably contains an oxidizing agent (A), a fluorine compound (B), and a metallic tungsten corrosion inhibiter (C). In this configuration, the addition ratio of the oxidizing agent (A) is preferably from 0.0001 to 10% by mass relative to the total mass of the etching agent. Moreover, the addition ratio of the fluorine compound (B) is preferably from 0.005 to 10% by mass relative to the total mass of the etching agent. Furthermore, the addition ratio of the metallic tungsten corrosion inhibiter (C) is preferably from 0.0001 to 5% by mass relative to the total mass of the etching agent. Hereinafter, the preferred etching agent will be described in detail. Note that, the term “Ti/W etching selectivity” as used herein means the etching selectivity of titanium and/or a titanium alloy over metallic tungsten, and specifically means the ratio of the etching rate of titanium and/or a titanium alloy to the etching rate of metallic tungsten (the etching rate of titanium and/or a titanium alloy divided by the etching rate of metallic tungsten).

### Oxidizing Agent (A)

The oxidizing agent (A) has a function such as rendering the oxidation number of titanium atoms in titanium or a titanium alloy into the tetravalent state, thereby making them soluble in an etching agent.

The oxidizing agent (A) is not particularly limited, and examples thereof include peroxy acids, halogen oxoacids, and salts thereof

Examples of the peroxy acids include hydrogen peroxide, persulfuric acid, percarbonic acid, perphosphoric acid, peracetic acid, perbenzoic acid, and meta-chloroperbenzoic acid.

Examples of the halogen oxoacids include: oxoacids of chlorine such as hypochlorous acid, chlorous acid, chloric acid, and perchloric acid; oxoacids of bromine such as hypobromous acid, bromous acid, bromic acid, and perbromic acid; and oxoacids of iodine such as hypoiodous acid, iodous acid, iodic acid, and periodic acid.

Examples of the salts include: alkali metal salts such as lithium salts, sodium salts, potassium salts, rubidium salts, and cesium salts of the peroxy acid or of halogen oxoacid; alkaline earth metal salts such as beryllium salts, magnesium salts, calcium salts, strontium salts, and barium salts of the peroxy acid or of the halogen oxoacid; metal salts such as aluminum salts, copper salts, zinc salts, and silver salts of the peroxy acid or of the halogen oxoacid; and ammonium salts of the peroxy acid or of halogen oxoacid.

The oxidizing agent (A) mentioned above is preferably hydrogen peroxide or an iodine oxoacid, more preferably hydrogen peroxide, iodic acid, or periodic acid, and in view of enhancing the Ti/W etching selectivity, the oxidizing agent (A) is still more preferably hydrogen peroxide or periodic acid, and particularly preferably periodic acid.

The oxidizing agent (A) mentioned above may be used singly, or two or more kinds thereof may be used in combination. In other words, in one embodiment, the oxidizing agent (A) preferably contains at least one selected from the group consisting of peroxy acids, halogen oxoacids, and salts thereof, more preferably contains at least one selected from the group consisting of hydrogen peroxide and iodine oxoacids, still more preferably contains at least one selected from the group consisting of hydrogen peroxide, iodic acid, and periodic acid, particularly preferably contains at least one selected from the group consisting of hydrogen peroxide and periodic acid, and most preferably contains periodic acid.

The addition ratio of the oxidizing agent (A) is preferably from 0.0001 to 10% by mass, more preferably from 0.001 to 5% by mass, still more preferably from 0.003 to 3% by mass, and particularly preferably from 0.01 to 2% by mass relative to the total mass of the etching agent.

### Fluorine Compound (B)

The fluorine compound (B) has a function such as facilitating the etching of titanium or titanium alloys.

The fluorine compound (B) is not particularly limited, and examples thereof include hydrogen fluoride (HF), tetrafluoroboric acid (HBF₄), hexafluorosilicic acid (H₂SiF₆), hexafluorozirconic acid (H₂ZrF₆), hexafluorotitanic acid (H₂TiF₆), hexafluorophosphoric acid (HPF₆), hexafluoroaluminic acid (H₂AlF₆), hexafluorogermanic acid (H₂GeF₆), and salts thereof.

In this configuration, examples of the salt include ammonium salts such as ammonium fluoride (NH₄F), ammonium hydrogen fluoride (NH₄·HF), ammonium tetrafluoroborate (NH₄BF₄), ammonium hexafluorosilicate ((NH₄)₂SiF₆), and tetramethylammonium tetrafluoroborate (N(CH₃)₄BF₄).

Among the above, the fluorine compound (B) is preferably hydrogen fluoride (HF), tetrafluoroboric acid (HBF₄), hexafluorosilicic acid (H₂SiF₆), or a salt thereof, more preferably hydrogen fluoride (HF), ammonium fluoride (NH₄F), ammonium hydrogen fluoride (NH₄·HF), or hexafluorosilicic acid (H₂SiF₆), and from the perspective of increasing the etching rate of titanium or titanium alloys, the fluorine compound (B) is still more preferably hydrogen fluoride (HF) or ammonium hydrogen fluoride (NH₄·HF), and particularly preferably ammonium hydrogen fluoride (NH₄·HF).

Note that the fluorine compound (B) mentioned above may be used singly, or two or more kinds thereof may be used in combination. In other words, in one preferred embodiment, the fluorine compound (B) preferably contains at least one selected from the group consisting of hydrogen fluoride (HF), tetrafluoroboric acid (HBF₄), hexafluorosilicic acid (H₂SiF₆), hexafluorozirconic acid (H₂ZrF₆), hexafluorotitanic acid (H₂TiF₆), hexafluorophosphoric acid (HPF₆), hexafluoroaluminic acid (H₂AlF₆), hexafluorogermanic acid (H₂GeF₆), and salts thereof, more preferably contains at least one selected from the group consisting of hydrogen fluoride (HF), tetrafluoroboric acid (HBF₄), hexafluorosilicic acid (H₂SiF₆), and salts thereof, still more preferably contains at least one selected from the group consisting of hydrogen fluoride (HF), ammonium fluoride (NH₄F), ammonium hydrogen fluoride (NH₄·HF) and hexafluorosilicic acid (H₂SiF₆), particularly preferably contains at least one selected from the group consisting of hydrogen fluoride (HF) and ammonium hydrogen fluoride (NH₄·HF), and most preferably contains ammonium hydrogen fluoride (NH₄·HF).

The addition ratio of the fluorine compound (B) is preferably from 0.005 to 10% by mass, more preferably from 0.01 to 5% by mass, still more preferably from 0.01 to 3% by mass, and particularly preferably from 0.03 to 1% by mass relative to the total mass of the etching agent.

### Metallic Tungsten Corrosion Inhibiter (C)

The metallic tungsten corrosion inhibiter (C) is adsorbed to metallic tungsten to form a protective film, thereby having a function such as preventing or suppressing the etching with an etching agent.

The metallic tungsten corrosion inhibiter (C) is not particularly limited, and examples thereof include: ammonium salts represented by Formula (1); and heteroaryl salts having an alkyl group with 5 to 30 carbon atoms.

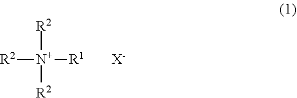

In Formula (1), R¹ represents an alkyl group with 5 to 30 carbon atoms, a substituted or unsubstituted alkyl(poly)heteroalkylene group, a substituted or unsubstituted aryl(poly)heteroalkylene group, or a group represented by Formula (2) below.

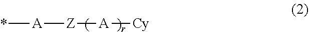

Here, in Formula (2), Cy represents a substituted or unsubstituted (hetero)cycloalkyl group, or a substituted or unsubstituted (hetero)aryl group, each A independently represents an alkylene with 1 to 5 carbon atoms, r is 0 or 1, and Z is any of the following formulae.

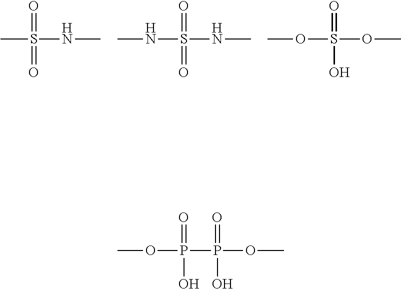

In Formula (2), the mark * represents a bonding position with a nitrogen (N) atom in Formula (1). As a result of this, the corrosion inhibiter is facilitated to adsorb on metallic tungsten and has an enhanced anti-corrosion function for metallic tungsten.

The alkyl group with 5 to 30 carbon atoms is not particularly limited, and examples thereof include pentyl group, hexyl group, heptyl group, octyl group, nonyl group, decyl group, undecyl group, dodecyl group, tridecyl group, tetradecyl group, pentadecyl group, hexadecyl group, heptadecyl group, octadecyl group, nonadecyl group, and icosyl group.

The alkyl(poly)heteroalkylene group is represented by —(CₙH₂ₙ—Z—)ₘ—R³. In the formula, each n independently represents an integer from 1 to 5, preferably from 1 to 3, and more preferably from 1 to 2. Each m represents an integer from 1 to 5, preferably from 1 to 2. Each Z is independently an oxygen atom (O), a sulfur atom (S), or a phosphorus atom (P), and is preferably an oxygen atom (O). R³ is an alkyl group with 1 to 30 carbon atoms, and examples thereof include methyl group, ethyl group, propyl group, isopropyl group, butyl group, pentyl group, hexyl group, heptyl group, octyl group, nonyl group, decyl group, undecyl group, dodecyl group, tridecyl group, tetradecyl group, pentadecyl group, hexadecyl group, heptadecyl group, octadecyl group, nonadecyl group, and icosyl group.

The alkyl(poly)heteroalkylene group may have a substituent. The said substituent is usually substituted with a hydrogen atom in R³. In the case where the alkyl(poly)heteroalkylene group has a substituent, the substituent is not particularly limited, and examples thereof include: aryl groups with 6 to 20 carbon atoms, such as phenyl group and naphthyl group; alkoxy groups with 1 to 6 carbon atoms, such as methoxy, ethoxy, and propyloxy groups; hydroxy group; cyano group; and nitro group. Note that the alkyl(poly)heteroalkylene group may have one substituent, or may have two or more substituents.

The aryl(poly)heteroalkylene group is represented by —(CₙH₂ₙ—Z—)ₘ—Ar. In the formula, each n independently represents an integer from 1 to 5, preferably from 1 to 3, and more preferably from 1 to 2. Each m represents an integer from 1 to 5, preferably from 1 to 2. Each Z is independently an oxygen atom (O), a sulfur atom (S), or a phosphorus atom (P), and is preferably an oxygen atom (O). Ar represents an aryl group with 6 to 18 carbon atoms, and examples thereof include phenyl group, naphthyl group, and anthracenyl group.

The aryl(poly)heteroalkylene group may have a substituent. The said substituent is usually substituted with a hydrogen atom in Ar. In the case where the aryl(poly)heteroalkylene group has a substituent, the substituent is not particularly limited, and examples thereof include: alkyl groups with 1 to 10 carbon atoms, such as methyl group, ethyl group, propyl group, isopropyl group, butyl group, 1,1-dimethylbutyl group, 2,2-dimethylbutyl group, and 1,1,3,3-tetramethylbutyl group; alkoxy groups with 1 to 6 carbon atoms, such as methoxy, ethoxy, and propyloxy groups; hydroxy group; cyano group; and nitro group. Note that the alkyl(poly)heteroalkylene group may have one substituent, or may have two or more substituents.

In Formula (2), Cy is a substituted or unsubstituted cycloalkyl group with 3 to 10 carbon atoms, a substituted or unsubstituted heterocycloalkyl group with 2 to 10 carbon atoms, a substituted or unsubstituted aryl group with 6 to 15 carbon atoms, or a substituted or unsubstituted heteroaryl group with 2 to 15 carbon atoms, and the cycloalkyl group with 3 to 10 carbon atoms is not particularly limited, and examples thereof include cyclopropyl group, cyclobutyl group, cyclopentyl group, and cyclohexyl group. The heterocycloalkyl group with 2 to 10 carbon atoms is not particularly limited, and examples thereof include pyrrolidinyl group, piperidyl group, tetrahydrofuranyl group, tetrahydropyranyl group, and tetrahydrothienyl group. The aryl group with 6 to 15 carbon atoms is not particularly limited, and examples thereof include phenyl group. The heteroaryl group with 2 to 15 carbon atoms is not particularly limited, and examples thereof include pyrrolyl group, imidazolyl group, pyrazolyl group, oxazolyl group, isoxazolyl group, thiazolyl group, isothiazolyl group, pyridyl group, pyrazyl group, pyridazyl group, pyrimidyl group, quinolyl group, and isoquinolyl group.

In the case where the cycloalkyl group with 3 to 10 carbon atoms, the heterocycloalkyl group with 2 to 10 carbon atoms, the aryl group with 6 to 15 carbon atoms, and the heteroaryl group with 2 to 15 carbon atoms each have a substituent, the substituent is not particularly limited, and examples thereof include: alkyl groups with 1 to 10 carbon atoms, such as methyl group, ethyl group, propyl group, isopropyl group, and butyl group; alkoxy groups with 1 to 6 carbon atoms, such as methoxy, ethoxy, and propyloxy groups; alkenyloxy groups such as vinyloxy group, butene-1-enoxy group, and groups represented by —OC(CF₃)═CF{(CF₃)₂}; aryl groups with 6 to 10 carbon atoms, such as phenyl group and tolyl group; heteroaryl groups with 3 to 10 carbon atoms, such as pyrrolyl group, pyridyl group, imidazolyl group, oxazolyl group, isoxazolyl group, pyrimidyl group, and 4-amino-2-oxo-1,2-dihydropyrimidine-1-yl group; hydroxy group; cyano group; nitro group; and alkoxy groups with 1 to 6 carbon atoms, such as methoxy, ethoxy, and propyloxy groups. Note that the alkyl(poly)heteroalkylene group may have one substituent, or may have two or more substituents.

Each A is independently an alkylene with 1 to 5 carbon atoms. The alkylene with 1 to 5 carbon atoms is not particularly limited, and examples thereof include methylene (—CH₂—), ethylene (—C₂H₄—), propylene (—C₃H₆—), and isopropylene (—CH(CH₃)CH₂—).

Moreover, r is 0 or 1.

Furthermore, Z is one of the following formulae.

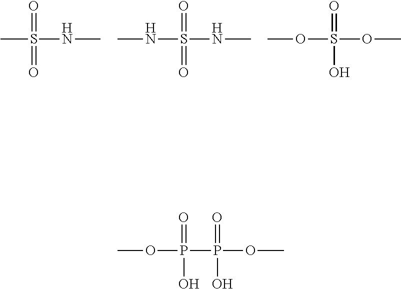

In the formulae, one or two of the hydroxy groups in the structure derived from monophosphoric acid or diphosphoric acid may be in the form of an anion. Specifically, it may have the following structures.

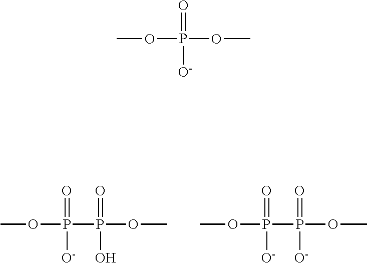

In this case, the counter ion of ammonium cation presents in R¹, and hence there are cases where ammonium salt X⁻ is not included in Formula (1).

The group represented by Formula (2) preferably includes the following structures.

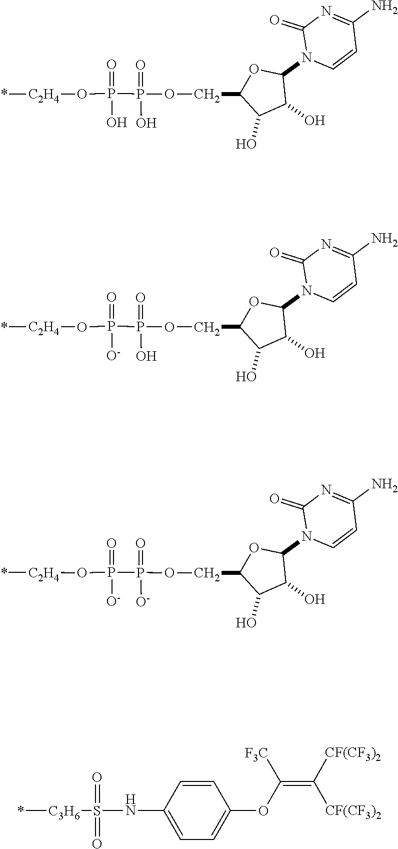

Among them, R¹ is preferably an alkyl group with 6 to 20 carbon atoms or a substituted or unsubstituted aryl(poly)oxyalkylene group, more preferably an alkyl group with 8 to 18 carbon atoms or a substituted or unsubstituted phenyl(poly)oxyalkylene group, and still more preferably an octyl group, a decyl group, a dodecyl group, a tetradecyl group, a hexadecyl group, an octadecyl group, a phenyl oxyethyl (Ph—O—C₂H₄—) group, a phenyldi(oxyethylene) (Ph—(O—C₂H₄)₂—) group, a p-(1, 1,3,3-tetramethylbutyl)phenyldi(oxyethylene) (p-CH₃C(CH₃)₂CH₂C(CH₃)₂—Ph—(O—C₂H₄)₂—) group.

Each R² is independently a substituted or unsubstituted alkyl group with 1 to 18 carbon atoms, or a substituted or unsubstituted aryl group with 6 to 20 carbon atoms.

The alkyl group with 1 to 18 carbon atoms is not particularly limited, and examples thereof include methyl group, ethyl group, propyl group, isopropyl group, butyl group, isobutyl group, sec-butyl group, tert-butyl group, pentyl group, hexyl group, heptyl group, octyl group, nonyl group, decyl group, dodecyl group, tetradecyl group, hexadecyl group, and octadecyl group.

In the case where the alkyl group with 1 to 18 carbon atoms has a substituent, examples of the substituent include: aryl groups with 6 to 20 carbon atoms, such as phenyl group and naphthyl group; alkoxy groups with 1 to 6 carbon atoms, such as methoxy, ethoxy, and propyloxy groups; hydroxy group; cyano group; and nitro group.

The aryl group with 6 to 20 carbon atoms is not particularly limited, and examples thereof include phenyl group, naphthyl group, and biphenyl group.

In the case where the aryl group with 6 to 20 carbon atoms has a substituent, examples of the substituent include: alkyl groups with 1 to 10 carbon atoms, such as methyl group, ethyl group, propyl group, and isopropyl group; alkoxy groups with 1 to 6 carbon atoms, such as methoxy, ethoxy, and propyloxy groups; hydroxy group; cyano group; and nitro group.

Among them, R² is preferably a substituted or unsubstituted alkyl group with 1 to 18 carbon atoms, more preferably a methyl group, an ethyl group, a propyl group, an isopropyl group, a hexyl group, an octyl group, a decyl group, a dodecyl group, a tetradecyl group, a hexadecyl group, an octadecyl group, a benzyl group, a hydroxymethyl group, or a 2-hydroxyethyl group, still more preferably a methyl group, an ethyl group, a benzyl group, or a 2-hydroxyethyl group, particularly preferably a methyl group or a benzyl group, and most preferably a methyl group. In another embodiment, R² is preferably an alkyl group with 1 to 10 carbon atoms substituted with an aryl group with 6 to 20 carbon atoms, more preferably an alkyl group with 1 to 5 carbon atoms substituted with a phenyl group, still more preferably a benzyl group or a phenylethyl group, and particularly preferably a benzyl group.

The X is a halide ion (fluoride ion, chloride ion, bromide ion, iodide ion, etc.), a hydroxide ion, an organic sulfonate ion (methanesulfonate ion, p-toluenesulfonate ion, etc.), a tetrafluoroborate, or a hexafluorophosphate. Among them, X is preferably a halide ion, and more preferably a chloride ion or a bromide ion.

Specific examples of the ammonium salt having an alkyl group with 5 to 30 carbon atoms include: ammonium salts having a hexyl group, such as hexyltrimethylammonium bromide; ammonium salts having a heptyl group, such as tetraheptylammonium bromide; ammonium salts having an octyl group, such as octyltrimethylammonium chloride and octyl dimethyl benzyl ammonium chloride; ammonium salts having a decyl group, such as decyltrimethylammonium chloride and decyldimethylbenzylammonium chloride; ammonium salts having a dodecyl group, such as dodecyltrimethylammonium chloride, dodecyltrimethylammonium bromide, dodecylethyldimethylammonium chloride, dodecylethyldimethylammonium bromide, benzyldodecyldimethylammonium chloride, benzyldodecyldimethylammonium bromide, tridodecylmethylammonium chloride, and tridodecylmethylammonium bromide; ammonium salts having a tetradecyl group, such as tetradecyltrimethylammonium bromide and benzyldimethyltetradecylammonium chloride; ammonium salts having a hexadecyl group, such as hexadecyltrimethylammonium chloride, hexadecyltrimethylammonium bromide, hexadecyltrimethylammonium p-toluenesulfonate, hexadecyltrimethylammonium hydroxide, ethylhexadecyldimethylammonium chloride, ethylhexadecyldimethylammonium bromide, and benzyldimethylhexadecylammonium chloride; and ammonium salts having an octadecyl group, such as trimethyloctadecylammonium chloride, trimethyloctadecylammonium bromide, dimethyldioctadecylammonium chloride, dimethyldioctadecylammonium bromide, and benzyldimethyloctadecylammonium chloride.

Specific examples of the ammonium salt having a substituted or unsubstituted alkyl(poly)heteroalkylene group include trimethylpropyldi(oxyethylene)ammonium chloride and trimethyl propyl (oxyethylenethioethylene)ammonium chloride.

Specific examples of the ammonium salt having a substituted or unsubstituted aryl(poly)heteroalkylene group include benzyldimethyl-2-{2-[4-(1,1,3,3-tetramethylbutyl)phenoxy]ethoxy}ethylammonium chloride (benzetonium chloride) and benzyldimethylphenyldi(oxyethylene)ammonium chloride.

Specific examples of the ammonium salt having a group represented by Formula (2) include compounds represented by the following structures.

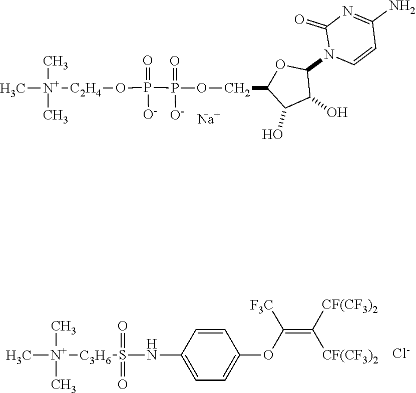

The heteroaryl salt having an alkyl group with 5 to 30 carbon atoms is not particularly limited, and examples thereof include salts of heteroaryl cations in which at least one of nitrogen atoms in a substituted or unsubstituted nitrogen atom-containing heteroaryl ring is bonded to an alkyl group with 5 to 30 carbon atoms.

The nitrogen atom-containing heteroaryl ring is not particularly limited, and examples thereof include rings such as imidazole, pyrazole, oxazole, isoxazole, thiazole, isothiazole, pyridine, pyrazine, pyridazine, pyrimidine, quinoline, and isoquinoline rings.

In the case where the nitrogen atom-containing heteroaryl ring has a substituent, examples of the substituent include: alkyl groups with 1 to 4 carbon atoms, such as methyl group, ethyl group, propyl group, and isopropyl group; aryl groups with 6 to 20 carbon atoms, such as phenyl group and naphthyl group; alkoxy groups with 1 to 6 carbon atoms, such as methoxy, ethoxy, and propyloxy groups; hydroxy group; cyano group; and nitro group.

The alkyl group with 5 to 30 carbon atoms is not particularly limited, and examples thereof include pentyl group, hexyl group, heptyl group, octyl group, nonyl group, decyl group, undecyl group, dodecyl group, tridecyl group, tetradecyl group, pentadecyl group, hexadecyl group, heptadecyl group, octadecyl group, nonadecyl group, and icosyl group.

Among them, the alkyl group with 5 to 30 carbon atoms is preferably an alkyl group with 6 to 20 carbon atoms, more preferably an alkyl group with 8 to 18 carbon atoms, and still more preferably an octyl group, a decyl group, a dodecyl group, a tetradecyl group, a hexadecyl group, or an octadecyl group.

The counter anion of the heteroaryl cation having an alkyl group with 5 to 30 carbon atoms is not particularly limited, but example thereof include: halide ions such as fluoride ion, chloride ion, bromide ion, and iodide ion; hydroxide ion; organic sulfonic acid ions such as methanesulfonic acid ion and p-toluenesulfonic acid ion; tetrafluoroborate; and hexafluorophosphate. Among them, the counter anion is preferably a halide ion, and more preferably a chloride ion or a bromide ion.

Specific examples of the heteroaryl salt having an alkyl group with 5 to 30 carbon atoms include: imidazolium salts such as, 1-methyl-3-hexylimidazolium chloride, 1-octyl-3-methylimidazolium chloride, 1-octyl-3-methylimidazolium bromide, 1-octyl-3-methylimidazolium tetrafluoroborate, 1-decyl-3-methylimidazolium chloride, 1-decyl-3-methylimidazolium bromide, 1-decyl-3-methylimidazolium tetrafluoroborate, 1-dodecyl-3-methylimidazolium chloride, 1-dodecyl-3-methylimidazolium bromide, 1-tetradecyl-3-methylimidazolium chloride, 1-tetradecyl-3-methylimidazolium bromide, 1-hexadecyl-3-methylimidazolium chloride, 1-hexadecyl-3-methylimidazolium bromide, 1-octadecyl-3-methylimidazolium chloride and 1-octadecyl-3-methylimidazolium bromide; oxazolium salts such as 3-dodecyl oxazolium chloride, 3-dodecyl oxazolium bromide, 3-tetradecyl oxazolium chloride and 3-hexadecyl oxazolium chloride; thiazolium salts such as 3-dodecylthiazolium chloride, 3-dodecylthiazolium bromide, 3-dodecyl-4-methylthiazolium chloride, 3-tetradecylthiazolium chloride and 3-hexadecylthiazolium chloride; pyridinium salts such as 1-hexylpyridinium chloride, 1-octylpyridinium chloride, 1-decylpyridinium chloride, 1-dodecylpyridinium chloride, 1-dodecylpyridinium bromide, 1-tetradecylpyridinium chloride, 1-tetradecylpyridinium bromide, 1-hexadecylpyridinium chloride, 1-hexadecylpyridinium bromide, 1-octadecylpyridinium chloride, and 1-octadecylpyridinium bromide; pyrimidinium salts such as 1-hexylpyrimidinium chloride, 1-hexylpyrimidinium hexafluorophosphate, 1-octylpyrimidinium chloride, 1-decylpyrimidinium chloride, 1-dodecylpyrimidinium chloride, 1-tetradecylpyrimidinium chloride, and 1-hexadecylpyrimidinium chloride; quinolinium salts such as dodecylquinolinium chloride, dodecylquinolinium bromide, tetradecylquinolinium chloride and hexadecylquinolinium chloride; and isoquinolinium salts such as dodecyl isoquinolinium chloride, dodecyl isoquinolinium bromide, tetradecyl isoquinolinium chloride and hexadecyl isoquinolinium chloride. Furthermore, they may be used as hydrates thereof

Among them, from the perspective of enhancing the Ti/W etching selectivity, the metallic tungsten corrosion inhibiter (C) is preferably an ammonium salt represented by Formula (1) (wherein R¹ is an alkyl group with 6 to 20 carbon atoms, and R² is an alkyl group with 1 to 10 carbon atoms, or an alkyl group with 1 to 10 carbon atoms substituted with an aryl group with 6 to 20 carbon atoms), an ammonium salt having a substituted or unsubstituted aryl(poly)heteroalkylene group, or a heteroaryl salt having an alkyl group with 5 to 30 carbon atoms, more preferably an ammonium salt represented by Formula (1) (wherein R¹ is an alkyl group with 8 to 20 carbon atoms, and R² is an alkyl group with 1 to 5 carbon atoms or an alkyl group with 1 to 5 carbon atoms substituted with a phenyl group), an ammonium salt having a substituted or unsubstituted phenyl(poly)oxyalkylene group, or an imidazolium salt having an alkyl group with 8 to 20 carbon atoms, still more preferably an octyltrimethylammonium salt, an octyl dimethyl benzyl ammonium salt, a decyltrimethylammonium salt, a decyldimethylbenzylammonium salt, a dodecyltrimethylammonium salt, a dodecyl dimethyl benzyl ammonium salt, a tetradecyltrimethylammonium salt, a tetradecyl dimethyl benzyl ammonium salt, a hexadecyltrimethylammonium salt, a hexadecyl dimethyl benzyl ammonium salt, an octadecyltrimethylammonium salt, an octadecyl dimethyl benzyl ammonium salt, an octyltriethylammonium salt, an octyl diethyl benzyl ammonium salt, a decyltriethylammonium salt, a decyl diethyl benzyl ammonium salt, a dodecyltriethylammonium salt, a dodecyldiethylbenzylammonium salt, a tetradecyltriethylammonium salt, a tetradecyldiethylbenzylammonium salt, a hexadecyltriethylbenzylammonium salt, a hexadecyldiethylbenzylammonium salt, an octadecyltriethylammonium salt, an octadecyldiethylbenzylammonium salt, an octylethylmethylbenzylamminium salt, a decylethylmethylbenzylammonium salt, a dodecylethylmethylbenzylammonium salt, a tetradecylethylmethylbenzylammonium salt, a hexadecylethylmethylbenzylammonium salt, an octadecylethylmethylbenzylammonium salt, a trimethyl-2-{2-[4-(1,1,3,3-tetramethylbutyl)phenoxy]ethoxy}ethylammonium chloride, a benzyldimethyl-2-{2-[4-(1,1,3,3-tetramethylbutyl)phenoxy]ethoxy}ethylammonium chloride (benzetonium chloride), a 1-octylimidazolium chloride, a 1-decylimidazolium chloride, a 1-dodecylimidazolium chloride, a 1-tetradecylimidazolium chloride, a 1-hexadecylimidazolium chloride, a 1-octadecylimidazolium chloride, a 1-octyl-3-methylimidazolium chloride, a 1-decyl-3-methylimidazolium chloride, a 1-dodecyl-3-methylimidazolium chloride, a 1-tetradecyl-3-methylimidazolium chloride, a 1-hexadecyl-3-methylimidazolium chloride, or a 1-octadecyl-3-methylimidazolium chloride, and particularly preferably an octyl dimethyl benzyl ammonium salt, a decyldimethylbenzylammonium salt, a dodecyl dimethyl benzyl ammonium salt, a tetradecyl dimethyl benzyl ammonium salt, a hexadecyl dimethyl benzyl ammonium salt, an octadecyl dimethyl benzyl ammonium salt, a 1-octyl-3-methylimidazolium chloride, a 1-decyl-3-methylimidazolium chloride, a 1-dodecyl-3-methylimidazolium chloride, a 1-tetradecyl-3-methylimidazolium chloride, a 1-hexadecyl-3-methylimidazolium chloride, or a 1-octadecyl-3-methylimidazolium chloride.

Note that, the metallic tungsten corrosion inhibiter (C) mentioned above may be used singly, or two or more kinds thereof may be used in combination. In other words, in one preferred embodiment, the metallic tungsten corrosion inhibiter (C) preferably contains at least one selected from the group consisting of ammonium salts having an alkyl group with 5 to 30 carbon atoms, ammonium salts having a substituted or unsubstituted aryl(poly)heteroalkylene group, and heteroaryl salts having an alkyl group with 5 to 30 carbon atoms, and from the perspective of enhancing the Ti/W etching selectivity, the metallic tungsten corrosion inhibiter (C) more preferably contains at least one selected from the group consisting of ammonium salts represented by Formula (1) (wherein R¹ is an alkyl group with 6 to 20 carbon atoms, and R² is an alkyl group with 1 to 10 carbon atoms, or an alkyl group with 1 to 10 carbon atoms substituted with an aryl group with 6 to 20 carbon atoms), ammonium salts having a substituted or unsubstituted phenyl(poly)oxyalkylene group, and heteroaryl salts having an alkyl group with 5 to 30 carbon atoms, still more preferably contains at least one selected from the group consisting of ammonium salts represented by Formula (1) (wherein R¹ is an alkyl group with 8 to 20 carbon atoms, and R² is an alkyl group with 1 to 10 carbon atoms, or an alkyl group with 1 to 5 carbon atoms substituted with a phenyl group) and imidazolium salts having an alkyl group with 8 to 20 carbon atoms, particularly preferably contains at least one selected from the group consisting of octyl trimethyl ammonium salt, octyl dimethyl benzyl ammonium salt, decyltrimethylammonium salt, decyldimethylbenzylammonium salt, dodecyltrimethylammonium salt, dodecyl dimethyl benzyl ammonium salt, tetradecyltrimethylammonium salt, tetradecyl dimethyl benzyl ammonium salt, hexadecyltrimethylammonium salt, hexadecyl dimethyl benzyl ammonium salt, octadecyltrimethylammonium salt, octadecyl dimethyl benzyl ammonium salt, octyltriethylammonium salt, octyl diethyl benzyl ammonium salt, decyltriethylammonium salt, decyl diethyl benzyl ammonium salt, dodecyltriethylammonium salt, dodecyl diethyl benzyl ammonium salt, tetradecyltriethylammonium salt, tetradecyldiethylbenzylammonium salt, hexadecyl triethyl ammonium salt, hexadecyldiethylbenzylammonium salt, octadecyltriethylammonium salt, octadecyldiethylbenzylammonium salt, octyl ethyl methyl benzyl ammonium salt, decylethylmethylbenzylammonium salt, dodecylethylmethylbenzylammonium salt, tetradecylethylmethylbenzylammonium salt, hexadecylethylmethylbenzylammonium salt, octadecylethylmethylbenzylammonium salt, trimethyl-2-{2-[4-(1,1,3,3-tetramethylbutyl)phenoxy]ethoxy}ethyl ammonium chloride, benzyldimethyl-2-{2-[4-(1,1,3,3-tetramethylbutyl)phenoxy]ethoxy}ethylammonium chloride (benzetonium chloride), 1-octylimidazolium chloride, 1-decylimidazolium chloride, 1-dodecylimidazolium chloride, 1-tetradecylimidazolium chloride, 1-hexadecylimidazolium chloride, 1-octadecylimidazolium chloride, 1-octyl-3-methylimidazolium chloride, 1-decyl-3-methylimidazolium chloride, 1-dodecyl-3-methylimidazolium chloride, 1-tetradecyl-3-methylimidazolium chloride, 1-hexadecyl-3-methylimidazolium chloride, and 1-octadecyl-3-methylimidazolium chloride, and most preferably contains at least one selected from the group consisting of octyl dimethyl benzyl ammonium salt, decyldimethylbenzylammonium salt, dodecyl dimethyl benzyl ammonium salt, tetradecyl dimethyl benzyl ammonium salt, hexadecyl dimethyl benzyl ammonium salt, octadecyl dimethyl benzyl ammonium salt, 1-octyl-3-methylimidazolium chloride, 1-decyl-3-methylimidazolium chloride, 1-dodecyl-3-methylimidazolium chloride, 1-tetradecyl-3-methylimidazolium chloride, 1-hexadecyl-3-methylimidazolium chloride, and 1-octadecyl-3-methylimidazolium chloride.

The addition ratio of the metallic tungsten corrosion inhibiter (C) is preferably from 0.0001 to 5% by mass, more preferably from 0.001 to 1% by mass, still more preferably from 0.003 to 0.5% by mass, and particularly preferably from 0.004 to 0.08% by mass relative to the total mass of the etching agent.

### pH Adjusting Agent

The etching agent optionally contains a pH adjusting agent. As the pH adjusting agent, there can be used, for example, an acid or an alkali with the exception of the oxidizing agent (A) and the fluorine compound (B).

Examples of the acid include hydrogen chloride, hydrogen bromide, hydrogen iodide, sulfuric acid, nitric acid, methanesulfonic acid, trifluoromethanesulfonic acid, benzenesulfonic acid, p-toluenesulfonic acid, 10-camphorsulfonic acid, and salts thereof. In this configuration, examples of the salt include: ammonium salts such as ammonium chloride, ammonium bromide, ammonium iodide, ammonium sulfate, and ammonium nitrate; alkylammonium salts such as methylamine hydrochloride, dimethylamine hydrochloride, dimethylamine hydrobromide, and methylamine sulfate.

Examples of the alkali include lithium hydroxide, sodium hydroxide, potassium hydroxide, rubidium hydroxide, cesium hydroxide, beryllium hydroxide, magnesium hydroxide, calcium hydroxide, strontium hydroxide, barium hydroxide, ammonia, and triethylamine.

Among the above, the pH adjusting agent is preferably hydrogen chloride, hydrogen bromide, hydrogen iodide, sulfuric acid, nitric acid, methanesulfonic acid, or ammonia, more preferably sulfuric acid, nitric acid, or ammonia, and still more preferably sulfuric acid or nitric acid.

### Solvent

The etching agent preferably contains a solvent. The solvent has functions such as uniformly dispersing and diluting each component contained in the etching agent.

Examples of the solvent include water and organic solvents.

The water mentioned above is not particularly limited, but is preferably water from which metal ions, organic impurities, particles and grains, and the like have been removed by distillation, ion exchange process, filtering process, various adsorption processes, or the like, more preferably pure water, and particularly preferably ultrapure water.

The organic solvent is not particularly limited, but examples thereof include: alcohols such as methanol, ethanol, 1-propanol, 2-propanol, 1-butanol, and tert-butanol; polyhydric alcohols such as ethylene glycol, propylene glycol, neopentyl glycol, 1,2-hexanediol, 1,6-hexanediol, 2-ethylhexane-1,3-diol, and glycerin; glycol ethers such as diethylene glycol monomethyl ether, diethylene glycol monoethyl ether, diethylene glycol monobutyl ether, propylene glycol monomethyl ether, propylene glycol monoethyl ether, dipropylene glycol monomethyl ether, tripropylene glycol monomethyl ether, dipropylene glycol dimethyl ether, dipropylene glycol monoethyl ether, propylene glycol n-propyl ether, dipropylene glycol n-propyl ether, tripropylene glycol n-propyl ether, propylene glycol n-butyl ether, dipropylene glycol n-butyl ether, tripropylene glycol n-butyl ether, and propylene glycol phenyl ether.

Among the above, the solvent is more preferably water. Note that, the solvent may be used singly, or two or more kinds thereof may be used in combination.

The addition ratio of the solvent, especially of water, is preferably 50% by mass or more, more preferably 80% by mass or more, still more preferably 90% by mass or more, and particularly preferably from 90 to 99.5% by mass relative to the total mass of the etching agent.

### Iodine Scavenger

When the oxidizing agent (A) contains an iodine oxoacid, the etching agent preferably further contains an iodine scavenger.

The iodine scavenger is not particularly limited, but examples thereof include: aliphatic ketones such as acetone, butanone, 2-methyl-2-butanone, 3,3-dimethyl-2-butanone, 4-hydroxy-2-butanone, 2-pentanone, 3-pentanone, 3-methyl-2-pentanone, 4-methyl-2-pentanone, 2-methyl-3-pentanone, 5-methyl-3-pentanone, 2,4-dimethyl-3-pentanone, 5-hydroxy-2-pentanone, 4-hydroxy-4-methyl-2-pentanone, 2-hexanone, 3-hexanone, 2-heptanone, 3-heptanone, 4-heptanone, 5-methyl-2-heptanone, 5-methyl-3-heptanone, 2,6-dimethyl-4-heptanone, 2-octanone, 3-octanone, 4-octanone, cyclohexanone, 2,6-dimethylcyclohexanone, 2-acetylcyclohexanone, menthone, cyclopentanone, and dicyclohexyl ketone; aliphatic diketones such as 2,5-hexanedione, 2,4-pentanedione, and acetylacetone; and aromatic ketones such as acetophenone, 1-phenylethanone, and benzophenone. Among them, the iodine scavenger is preferably an aliphatic ketone, more preferably 4-methyl-2-pentanone, 5-methyl-3-pentanone, 2,4-dimethyl-3-pentanone, or cyclohexanone, and still more preferably 4-methyl-2-pentanone. Note that, the iodine scavenger may be used singly, or two or more kinds thereof may be used in combination.

### Low Dielectric Constant Passivation Agent

The etching agent may further include a low dielectric constant passivation agent. The low dielectric constant passivation agent has a function to prevent or suppress the etching of a low dielectric constant film (e.g., an insulating film).

The low dielectric constant passivation agent is not particularly limited, but examples thereof include: boric acid; borates such as ammonium pentaborate and sodium tetraborate; and carboxylic acids such as 3-hydroxy-2-naphthoic acid, malonic acid, and iminodiacetic acid.

The low dielectric constant passivation agent may be used singly, or two or more kinds thereof may be used in combination.

The addition ratio of the low dielectric constant passivation agent is preferably from 0.01 to 2% by mass, more preferably from 0.02 to 1% by mass, and still more preferably from 0.03 to 0.5% by mass relative to the total mass of the etching agent.

### Additive

The etching agent may further include an additive. Examples of the additive include surfactants, chelating agents, antifoaming agents, and silicon-containing compounds.

### Physical Properties of Etching Agent

The etching agent preferably has a pH ranging from 0.5 to 5.0, more preferably from 1.0 to 4.0, and still more preferably from 1.0 to 3.0.

The etching rate of metallic tungsten with the etching agent is preferably 5.0 Å/min or less, more preferably 3.0 Å/min or less, still more preferably 2.0 Å/min or less, particularly preferably 1.5 Å/min or less, and most preferably from 0.1 to 1.0 Å/min. The etching rate of the metallic tungsten being 5.0 Å/min or less is preferable since the Ti/W etching selectivity is enhanced. Note that the etching rate of metallic tungsten with the etching agent means a value measured by the method used in Examples.

The etching rate of titanium or titanium alloys with the etching agent is preferably 10 Å/min or more, more preferably 30 Å/min or more, still more preferably 50 Å/min or more, further more preferably 60 Å/min, and particularly preferably 80 Å/min or more. The etching rate of titanium or titanium alloys being 10 Å/min or more is preferable since the Ti/W etching selectivity is enhanced. Note that, the etching rate of titanium or titanium alloys with the etching agent means a value measured by the method used in Examples.

The etching rate of the insulating layer material with the etching agent is preferably 5.0 Å/min or less, more preferably 3.0 Å/min or less, still more preferably 2.0 Å/min or less, particularly preferably 1.5 Å/min or less, and most preferably 1.0 Å/min or less. The etching rate of the insulating layer material being 5.0 Å/min or less is preferable since the semiconductor substrate retains its shape and is enhanced in performance as a semiconductor element. Note that the etching rate of the insulating layer material with the etching agent means a value measured by the method used in Examples.

The Ti/W etching selectivity (the etching rate of titanium and/or a titanium alloy divided by the etching rate of metallic tungsten) with the etching agent is preferably 10 or more, more preferably 30 or more, still more preferably 35 or more, particularly preferably 70 or more, and most preferably 100 or more. The Ti/W etching selectivity being 10 or more is preferable since a semiconductor substrate for memory elements having high performance can be produced.

### (Contact)

The method of bringing the semiconductor substrate after being subjected to the step (1) into contact with the etching agent is not particularly limited, and a known technique can be appropriately adopted. Specifically, the semiconductor substrate may be immersed in the etching agent, the etching agent may be sprayed onto the semiconductor substrate, or the etching agent may be dropped onto the semiconductor substrate (single wafer spin processing etc.). In this occasion, the immersion may be repeated two or more times, the spraying may be repeated two or more times, the dropping may be repeated two or more times, or the immersion, the spraying, and the dropping may be combined.

The contact temperature is not particularly limited, but is preferably from 0 to 90° C., more preferably from 15 to 70° C., and still more preferably from 20 to 60° C.

The contact time is not particularly limited, but is preferably from 10 seconds to 3 hours, more preferably from 30 seconds to 1 hour, still more preferably from 1 to 45 minutes, and particularly preferably from 1 to 5 minutes.

By bringing the semiconductor substrate after being subjected to the step (1) into contact with the etching agent, selective etching of titanium and/or a titanium alloy can be performed. In this occasion, since at least a part of the tungsten oxide film is removed in the step (1), the selective etching of titanium and/or a titanium alloy with the etching agent more suitably proceeds.

### (Semiconductor Substrate for Memory Elements)

The semiconductor substrate for memory elements obtained by the step (2) can be used for memory elements such as DRAM. The memory element obtained by the step (2) is enabled to be miniaturized and to have advanced features.

### <Kit>

According to one embodiment of the present invention, a kit is provided. The kit includes the above-mentioned pretreatment agent and the above-mentioned etching agent. That is, the kit is used in applications of producing a semiconductor substrate for memory elements. The provision of the pretreatment agent and the etching agent as a kit brings about benefits in carrying out the step (1) and step (2) when performing the selective etching of titanium and/or a titanium alloy in a semiconductor substrate including a tungsten oxide film.

### EXAMPLES

Hereinafter, the present invention will be specifically described with reference to Examples, but the present invention is not limited thereto.

### Example 1

### (Step (1))

A substrates having a tungsten oxide (WO₃) film, a substrate having a metallic tungsten (W) film, a substrate having a titanium nitride (TiN) film, and a substrate having a silicon oxide (th-Ox) film were prepared, and each of the substrates was subjected to the step (1), and the etching rate with the pretreatment agent for each of the films was measured.

A pretreatment agent was prepared. Specifically, hydrogen fluoride (HF) as a WO₃ etchant was added to pure water and the mixture was stirred to prepare a pretreatment agent. In this occasion, the addition ratio of the hydrogen fluoride was 0.1% by mass relative to the total mass of the pretreatment agent. Note that the pretreatment agent had a pH of 2.2. The pH of the pretreatment agent was measured at 23° C. with a tabletop pH meter (F-71) and a pH electrode (9615S-10D) manufactured by HORIBA, Ltd.

### (1-A) Treatment of Substrate Having Tungsten Oxide (WO₃) Film

Tungsten oxide (WO₃) was deposited on a silicon wafer by physical vapor deposition until the tungsten oxide film formed thereon had a thickness of 3000 Å, and the wafer was cut into a size of 1 cm×1 cm (immersion treatment area: 1 cm²) to prepare tungsten oxide film deposited samples.

The tungsten oxide film deposited sample was immersed in 10 g of the prepared pretreatment agent at a predetermined treatment temperature for 5 minutes. The pretreatment agent after the immersion treatment was diluted 10 to 20 times with a 1% by mass aqueous solution of nitric acid to prepare a measurement sample. The tungsten concentration in the measurement sample was determined with the ICP Optical Emission Spectrometer (ICP-OES): Avio 200 (manufactured by PerkinElmer).

In this occasion, samples for creating calibration curve were prepared by the following method. That is, a tungsten standard solution (tungsten concentration: 1000 ppm, manufactured by FUJIFILM Wako Pure Chemical Corporation) was diluted with a 1% by mass aqueous solution of nitric acid to prepare samples for creating calibration curves having tungsten concentrations of 25 ppb, 12.5 ppb, and 2.5 ppb.

The tungsten concentration of the measurement sample was determined by using the samples for creating calibration curve, the tungsten concentration before dilution was calculated from the tungsten concentration of the measurement sample, and the tungsten concentration before dilution and the amount of the pretreatment agent used for the measurement (the amount of the measurement sample before dilution) were put into the following equation to calculate the etching amount of the tungsten oxide film.

$$Etching amount of {WO}_{3} ( Å ) = \frac{\begin{matrix}W concentration before dilution ( ppb ) \times \\ 100 \times Amount of pretreatment agent used ( mL ) \times \\ 231.84 ( g / mol )\end{matrix}}{1000 \times 7.16 ( g / {cm}^{3} ) \times 1 ( {cm}^{2} ) \times 183.83 ( g / mol )}$$

Note that, in the equation above, 231.84 (g/mol) is the molecular weight of tungsten oxide (WO₃), 7.16 (g/cm³) is the density of tungsten oxide, 1 cm² is the immersion treatment area of the tungsten oxide film deposited sample, and 183.84 (g/mol) is the molecular weight of metallic tungsten (W).

The calculated etching amount of the tungsten oxide film was divided by the time duration of immersion treatment with the pretreatment agent to calculate the etching rate (E.R.) of the tungsten oxide film. As a result, the etching rate (E.R.) of the tungsten oxide film with the pretreatment agent was determined to be 31 Å/min.

### (1-B) Treatment of Substrate Having Metallic Tungsten (W) Film

Tungsten (W) was deposited on a silicon wafer by physical vapor deposition until the tungsten film formed thereupon had a thickness of 1000 Å, and then the wafer was cut into a size of 1 cm×1 cm (immersion treatment area: 1 cm²) to prepare metallic tungsten film deposited samples.

With the exception that the metallic tungsten film deposited sample was used and that the immersion treatment time was 2 minutes, a measurement sample was prepared in the same manner as in the method for measuring the etching rate of the tungsten oxide film, and the tungsten concentration in the measurement sample was measured.

The tungsten concentration of the measurement sample was determined by using the samples for creating calibration curve, the tungsten concentration before dilution was calculated from the tungsten concentration of the measurement sample, and the tungsten concentration before dilution and the amount of the pretreatment agent used for the measurement (the amount of the measurement sample before dilution) were put into the following equation to calculate the etching amount of the metallic tungsten film.

$$Etching amount of W ( Å ) = \frac{\begin{matrix}W concentration before dilution ( ppb ) \times \\ 100 \times Amount of pretreatment agent used ( mL )\end{matrix}}{1000 \times 19.25 ( g / {cm}^{3} ) \times 1 ( {cm}^{2} )}$$

Note that, in the equation above, 19.25 (g/cm³) is the density of metallic tungsten, and 1 cm² is the immersion treatment area of the tungsten film deposited sample.

The calculated etching amount of the metallic tungsten film was divided by the time duration of immersion treatment with the pretreatment agent to calculate the etching rate (E.R.) of the metallic tungsten film. As a result, the etching rate (E.R.) of the metallic tungsten film with the pretreatment agent was determined to be 2.5 Å/min.

### (1-C) Treatment of Substrate Having Titanium Nitride (TiN) Film

Titanium nitride (TiN) was deposited on a silicon wafer by physical vapor deposition until the titanium nitride film formed thereupon had a thickness of 1000 Å, and the wafer was then cut into a size of 2 cm×2 cm (immersion treatment area: 4 cm²) to prepare titanium nitride film deposited samples.

The film thickness of the titanium nitride film deposited sample was determined with the X-ray fluorescence analyzer EA-1200VX (manufactured by Hitachi High-Tech Corporation).

The titanium nitride film deposited sample was immersed in 10 g of the prepared pretreatment agent at a predetermined treatment temperature for 5 minutes.

The film thickness of the titanium nitride film deposited sample after the immersion treatment with the pretreatment agent was measured by the same method as described above.

The difference in the film thickness of the titanium nitride film deposited sample between before and after the immersion treatment with the pretreatment agent was calculated, and was divided by the time duration of immersion treatment with the pretreatment agent to calculate the etching rate (E.R.) of the titanium nitride film. As a result, the etching rate (E.R.) of the titanium nitride film with the pretreatment agent was determined to be 5 Å/min.

(1-D) Treatment of Substrate Having Silicon Oxide (th-Ox) Film

Silicon wafer was thermally oxidized until the silicon oxide film formed thereon had a thickness of 1000 Å, and the wafer was then cut into a size of 1 cm×1 cm (immersion treatment area: 1 cm²) to prepare silicon oxide film formed samples.

The film thickness of the silicon oxide film formed sample was determined with the optical coating thickness gauge n&k1280 (manufactured by n&k Technology Inc.).

The silicon oxide film formed sample was immersed in 10 g of the prepared pretreatment agent at a predetermined treatment temperature for 30 minutes.

The film thickness of the silicon oxide film formed sample after the immersion treatment was measured by the same method as described above.

The difference in the film thickness of the silicon oxide film formed samples between before and after the treatment was calculated, and was divided by the time duration of immersion treatment with the pretreatment agent to calculate the etching rate (E.R.) of the silicon oxide film. As a result, the etching rate (E.R.) of the silicon oxide film with the pretreatment agent was determined to be 2.8 Å/min.

### (1-E) Calculation of WO₃/W Etching Selectivity

The etching rate (E.R.) of the tungsten oxide film with the pretreatment agent was divided by the etching rate (E.R.) of the metallic tungsten film with the pretreatment agent to calculate the WO₃/W etching selectivity. As a result, the WO₃/W etching selectivity was determined to be 12.

### (Step (2))

A substrate having a metallic tungsten (W) film, a substrate having a titanium nitride (TiN) film, and a substrate having a silicon oxide (th-Ox) film were subjected to the step (2), and the etching rate of each of the films with the etching agent was measured. Note that, the titanium nitride film deposited sample after being subjected to the step (1) was used for the substrate having a titanium nitride (TiN) film. Another metallic tungsten film deposited sample and another silicon oxide film formed sample were newly prepared by the same method as in the step (1) and were used for the substrate having a metallic tungsten (W) film and the substrate having a silicon oxide (th-Ox) film, respectively.

An etching agent was prepared. Specifically, iodic acid (HIO₃) as an oxidizing agent, hydrogen fluoride (HF) as a fluorine compound, and 1-dodecylpyridinium chloride (DPC) as a metallic tungsten corrosion inhibiter were added to pure water, and the mixture was stirred to prepare an etching agent. In this configuration, the addition ratios of iodic acid, hydrogen fluoride, and 1-dodecylpyridinium chloride (DPC) were 0.018% by mass, 0.05% by mass, and 0.005% by mass, respectively, relative to the total mass of the etching agent. The etching agent had a pH of 2.4.

### (2-A) Treatment of Substrate Having Metallic Tungsten (W) Film

The metallic tungsten film deposited sample was immersed in 10 g of the prepared etching agent at a predetermined treatment temperature for 2 minutes. Thereafter, the etching rate (E.R.) of the metallic tungsten film was calculated by the same method as in the above-described (1-B). As a result, the etching rate (E.R.) of the metallic tungsten film with the etching agent was determined to be 2.1 Å/min.

### (2-B) Treatment of Substrate Having Titanium Nitride (TiN) Film After Being Subjected to the Step (1)

The titanium nitride film deposited sample after being subjected to the step (1) was immersed in 10 g of the prepared etching agent at a predetermined treatment temperature for 2 minutes. Thereafter, the etching rate (E.R.) of the titanium nitride film was calculated in the same manner as in the above-described (1-C). As a result, the etching rate (E.R.) of the titanium nitride film with the etching agent was determined to be 85 Å/min.

(2-C) Treatment of Substrate Having Silicon Oxide (th-Ox) Film

The silicon oxide film formed sample was immersed in 10 g of the prepared etching agent at a predetermined treatment temperature for 30 minutes. Thereafter, the etching rate (E.R.) of the silicon oxide film was calculated in the same manner as in the above-described (1-D). As a result, the etching rate (E.R.) of the silicon oxide film with the etching agent was determined to be 0.8 Å/min.

### (2-D) TiN/W Etching Selectivity

The etching rate (E.R.) of the titanium nitride film with the etching agent was divided by the etching rate (E.R.) of the metallic tungsten film with the etching agent to calculate the TiN/W etching selectivity. As a result, the TiN/W etching selectivity was determined to be 40.

### [Evaluation]

With respect to the pretreatment agent, the corrosion potential difference of metallic tungsten (W) minus titanium nitride (TiN) and the titanium oxide removal performance were evaluated.

### (Corrosion Potential Difference of Metallic Tungsten (W) Minus Titanium Nitride (TiN))

The corrosion potential of metallic tungsten (W) was measured by the following method. That is, a linear sweep voltammetry was carried out with use of HZ7000 manufactured by HOKUTO DENKO CORPORATION. Specifically, a metallic tungsten film after having been immersed in a 0.5% by mass aqueous solution of ammonia at 23° C. for 1 minute was used as a working electrode, platinum was used as a counter electrode, silver/silver chloride (in 3.3 M aqueous solution of potassium chloride) was used as a reference electrode, and a salt bridge (ager with 0.5 M potassium chloride) was used in the measurement. An electrical potential was applied to the metallic tungsten at a rate of 2 mV/sec from a potential lower than the corrosion potential by 30 mV to 200 mV, and the current value at each potential was plotted (Tafel plot). The potential with the lowest current value was defined as the corrosion potential of the metallic tungsten. As the result, the corrosion potential of the metallic tungsten (W) was determined to be −109 mV.

The corrosion potential of the titanium nitride (TiN) was measured by the following method. That is, a linear sweep voltammetry was carried out with use of HZ7000 manufactured by HOKUTO DENKO CORPORATION. Specifically, a titanium nitride film after having been immersed in a 1% by mass aqueous solution of hydrogen fluoride at 23° C. for 1 minute was used as a working electrode, platinum was used as a counter electrode, silver/silver chloride (in 3.3 M aqueous solution of potassium chloride) was used as a reference electrode, and a salt bridge (agar with 0.5 M potassium chloride) was used in the measurement. An electrical potential was applied to the titanium nitride at a rate of 2 mV/sec from a potential lower than the corrosion potential by 30 mV to 200 mV, and the current value at each potential was plotted (Tafel plot). The potential with the lowest current value was defined as the corrosion potential of the titanium nitride. As the result, the corrosion potential of the titanium nitride (TiN) was determined to be −73 mV.

The difference in corrosion potential between metallic tungsten (W) and titanium nitride (TiN) (the corrosion potential of W minus the corrosion potential of TiN) was calculated and determined to be 36 mV.

### (Titanium Oxide Removal Performance)

Titanium nitride (TiN) was deposited on a silicon wafer by physical vapor deposition until the titanium nitride film formed thereon had a thickness of 1000 Å, and the wafer was cut into a size of 2 cm×2 cm (immersion treatment area: 4 cm²). Subsequently, the wafer was exposed to air at 20° C. for 30 days, thereby oxidizing the surface of the deposited titanium nitride film to prepare a sample for measuring titanium oxide removal performance.

The sample for measuring titanium oxide removal performance was immersed in 10 g of the pretreatment agent (0.1% by mass aqueous solution of HF), which was prepared in the step (1), at 30° C. for 5 minutes to obtain a post-pretreatment sample. Subsequently, by using the etching agent prepared in the step (2), the etching rate (E.R.) of the titanium nitride film was calculated in the same manner as in (2-B), and was determined to be 85 Å/min. Note that it can be said that the higher the etching rate (E.R.) of the titanium nitride film, the more the titanium oxide film was able to be removed with the pretreatment agent in the step (1).

### Examples 1-2 to 1-10

As shown in Table 1 below, components to be added and the like were changed to prepare pretreatment agents. Table 1 below shows the compositions and the like of the pretreatment agents in Examples 1-2 to 1-10 along with the composition and the like in Example 1.

TABLE 1

| | WO₃ etchant | Concentration (% by mass) | pH |
|---|---|---|---|
| Example 1 | HF | 0.1 | 2.2 |
| Example 1-2 | Hydrogen chloride | 0.5 | 1.0 |
| Example 1-3 | Nitric acid | 0.5 | 1.2 |
| Example 1-4 | Sulfuric acid | 0.5 | 1.3 |
| Example 1-5 | Phosphoric acid | 0.5 | 1.8 |
| Example 1-6 | Acetic acid | 0.5 | 2.9 |
| Example 1-7 | NH₄F | 0.1 | 6.4 |
| Example 1-8 | Ammonia | 0.5 | 11.5 |
| Example 1-9 | TEAH* | 0.5 | 12.8 |
| Example 1-10 | TMAH* | 0.5 | 12.9 |

*TEAH: Tetraethylammonium hydroxide
TMAH: Tetramethylammonium hydroxide

The step (1) was performed in the same manner as in Example 1. Table 2 below shows the measurement results of the etching rates (E.R.) of tungsten oxide (W) film, of metallic tungsten (W) film, of titanium nitride (TiN) film, and of silicon oxide film; WO₃/W etching selectivity; the corrosion potential of metallic tungsten (W), the corrosion potential of titanium nitride (TiN), and the corrosion potential difference of metallic tungsten (W) minus titanium nitride (TiN); and the titanium oxide removal performance in Examples 1-2 to 1-10 along with the results of Example 1. Note that, the etching agent used in the measurement of the titanium oxide removal performance was the same as the etching agent used in Example 1.

TABLE 2

| | | | | | | | | | Corrosion | Titanium oxide |
|---|---|---|---|---|---|---|---|---|---|---|
| | Treatment | | | | | WO₃/W | | | Potential | removal performance |
| | temperature | E.R. (Å/min) | | | | etching | Corrosion potential (mV) | | difference | (E.R. of TiN) |
| | (° C.) | WO₃ | W | TiN | th-Ox | selectivity | W | TiN | (mV) | (Å/min) |
| Example 1 | 30 | 31 | 2.5 | 5 | 2.8 | 12 | −109 | −73 | 36 | 85 |
| Example 1-2 | 50 | 64 | 3.2 | <1 | <0.1 | 20 | −85 | −83 | 2 | 2 |
| Example 1-3 | 50 | 41 | 2.9 | 1 | <0.1 | 14 | −85 | −105 | −20 | <1 |
| Example 1-4 | 50 | 48 | 3.0 | 3 | <0.1 | 16 | −80 | −52 | 28 | 2 |
| Example 1-5 | 50 | 44 | 2.3 | 5 | 0.1 | 19 | −127 | −123 | 4 | <1 |
| Example 1-6 | 50 | 29 | 2.5 | 3 | 0.2 | 12 | −177 | −85 | 92 | <1 |
| Example 1-7 | 50 | 325 | 4.4 | 3 | <0.1 | 75 | −305 | −155 | 150 | <1 |
| Example 1-8 | 50 | 232 | 6.0 | <1 | 0.4 | 39 | −540 | −321 | 219 | 13 |
| Example 1-9 | 50 | 234 | 4.9 | <1 | 0.2 | 48 | −631 | −393 | 238 | 17 |
| Example 1-10 | 50 | 407 | 8.3 | <1 | 0.3 | 49 | −617 | −385 | 232 | 16 |

It can be seen from the results in Table 2 that the etching rates (E.R.) of WO₃ were high in any of Example 1 and Examples 1-2 to 1-10. Hence, the etching of metallic tungsten during pretreatment can be prevented without lowering the throughput in Example 1 and Examples 1-2 to 1-10. For this reason, by carrying out the step (2) with the semiconductor substrate obtained in the step (1), a semiconductor substrate for high-performance memory elements can be produced with high production efficiency.

### Examples 2-2 to 2-10

As shown in Table 3 below, the components to be added and the like were changed to prepare etching agents. Table 3 below shows the compositions and the like of the etching agents of Examples 2-2 to 2-10 along with the composition and the like of the etching agent of Example 1.

TABLE 3

| | Oxidizing agent (A) | | Fluorine compound (B) | | W corrosion inhibiter (C) | | |
|---|---|---|---|---|---|---|---|
| | | Concentration | | Concentration | | Concentration | |
| | Type | (% by mass) | Type | (% by mass) | Type* | (% by mass) | pH |
| Example 1 | Iodic acid | 0.018 | HF | 0.05 | DCP | 0.005 | 2.4 |
| Example 2-2 | Hydrogen | 0.500 | HF | 0.05 | DCP | 0.005 | 2.4 |
| | peroxide | | | | | | |
| Example 2-3 | Periodic | 0.058 | HF | 0.05 | DCP | 0.005 | 2.3 |
| | acid | | | | | | |
| Example 2-4 | Iodic acid | 0.018 | NH₄F HF | 0.143 | DCP | 0.005 | 3.1 |
| Example 2-5 | Iodic acid | 0.018 | H₂SiF₆ | 0.5 | DCP | 0.005 | 1.4 |
| Example 2-6 | Iodic acid | 0.018 | HF | 0.05 | CPC | 0.001 | 2.4 |
| Example 2-7 | Iodic acid | 0.018 | HF | 0.05 | DMIC | 0.005 | 2.4 |
| Example 2-8 | Iodic acid | 0.018 | HF | 0.05 | CTAB | 0.005 | 2.4 |
| Example 2-9 | Iodic acid | 0.018 | HF | 0.05 | OMIC | 0.2 | 2.5 |
| Example 2-10 | Iodic acid | 0.018 | HF | 0.05 | BZC | 0.001 | 2.3 |

*DCP: 1-Dodecyl pyridinium chloride
CPC: Hexadecyl pyridinium chloride monohydrate
DMIC: 1-Dodecy1-3-methylimidazolium chloride
CTAB: Hexadecyl trimethyl ammonium bromide
OMIC: 1-Octyl-3-methylimidazolium chloride
BZC: Benzalkonium Chloride

Note that DPC, CPC, DMIC, CTAB, OMIC, and BZC used in Examples have the following structures.

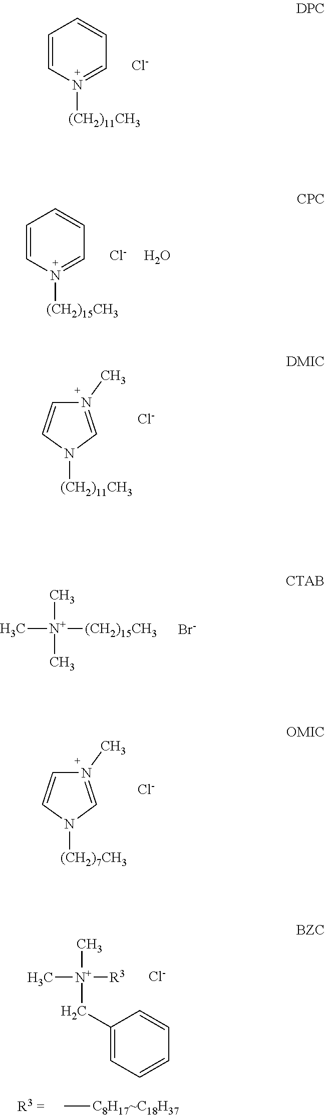

In the same manner as in Example 1, a substrate having a metallic tungsten (W) film, a substrate having a titanium nitride (TiN) film, and a substrate having a silicon oxide (th-Ox) film were subjected to the step (2). Note that, the titanium nitride film deposited sample after being subjected to the step (1) was used for the substrate having a titanium nitride (TiN) film. Another metallic tungsten film deposited sample and another silicon oxide film formed sample were newly prepared by the same method as in the step (1) and were used for the substrate having a metallic tungsten (W) film and the substrate having a silicon oxide (th-Ox) film, respectively. Table 4 below shows the measurement results of the etching rates (E.R.) of metallic tungsten (W) film, of titanium nitride (TiN) film, and of silicon oxide film; and the TiN/W etching selectivity of Examples 2-2 to 2-10 along with the results of Example 1.

TABLE 4

| | E.R. (Å/min) | | | TiN/W |
|---|---|---|---|---|
| | W | TiN | th-Ox | etching selectivity |
| Example 1 | 2.1 | 85 | 0.8 | 40 |
| Example 2-2 | 0.5 | 69 | 1.0 | 140 |
| Example 2-3 | 0.7 | 134 | 0.9 | 200 |
| Example 2-4 | 2.0 | 134 | 3.1 | 67 |
| Example 2-5 | 1.1 | 47 | 0.3 | 42 |
| Example 2-6 | 1.5 | 54 | 1.8 | 36 |
| Example 2-7 | 1.1 | 87 | 1.4 | 79 |
| Example 2-8 | 1.2 | 15 | 2.5 | 12 |
| Example 2-9 | 1.6 | 107 | 1.1 | 67 |
| Example 2-10 | 1.2 | 80 | 0.7 | 66 |

It can be seen from the results in Table 4 that tungsten oxide is efficiently removed in the step (1) in Example 1 and Examples 2-2 to 2-10, and hence titanium nitride can be selectively etched in the step (2), so that a semiconductor substrate for high-performance memory elements can be produced with high production efficiency.

### REFERENCE SIGNS LIST

10 Semiconductor substrate (before being subjected to the step (1))
11 Silicon substrate with a recess
12 Insulating film
13 Barrier film
14 Metallic tungsten film
15 Tungsten oxide film
16 Titanium oxide film
20 Semiconductor substrate (after being subjected to the step (1))
21 Silicon substrate with a recess
22 Insulating film
23 Barrier film
24 Metallic tungsten film
30 Semiconductor substrate (after being subjected to the step (2))
31 Silicon substrate with a recess
32 Insulating film
33 Etched barrier film
34 Metallic tungsten film

1. A method for producing a semiconductor substrate for memory elements, comprising:
a step (1) of bringing a semiconductor substrate including a titanium-containing film that contains at least one of titanium and a titanium alloy, a metallic tungsten film, and a tungsten oxide film into contact with a pretreatment agent to remove at least a part of the tungsten oxide film; and
a step (2) of bringing the semiconductor substrate after being subjected to the step (1) into contact with an etching agent to remove at least a part of the titanium-containing film,
wherein the pretreatment agent includes at least one tungsten oxide etchant selected from the group consisting of acids, ammonia, and ammonium salts.

2. The method for producing a semiconductor substrate for memory elements according to claim 1, wherein the pretreatment agent has a pH ranging from 0.1 to 13.

3. The method for producing a semiconductor substrate for memory elements according to claim 1, wherein the tungsten oxide etchant contains at least one selected from the group consisting of hydrogen fluoride, hydrogen chloride, hydrogen bromide, hydrogen iodide, sulfuric acid, nitric acid, and phosphoric acid.

4. The method for producing a semiconductor substrate for memory elements according to claim 1,
wherein the semiconductor substrate further includes a titanium oxide film, and the step (1) further includes removing at least a part of the titanium oxide film.

5. The method for producing a semiconductor substrate for memory elements according to claim 1,
wherein the etching agent contains an oxidizing agent (A), a fluorine compound (B), and a metallic tungsten corrosion inhibiter (C),
wherein an addition ratio of the oxidizing agent (A) is from 0.0001 to 10% by mass relative to a total mass of the etching agent;
an addition ratio of the fluorine compound (B) is from 0.005 to 10% by mass relative to a total mass of the etching agent; and
an addition ratio of the metallic tungsten corrosion inhibiter (C) is from 0.0001 to 5% by mass relative to a total mass of the etching agent.

6. The method for producing a semiconductor substrate for memory elements according to claim 5, wherein the oxidizing agent (A) contains at least one selected from the group consisting of peroxy acids, halogen oxoacids, and salts thereof.

7. The method for producing a semiconductor substrate for memory elements according to claim 5 or 6, wherein the fluorine compound (B) contains at least one selected from the group consisting of hydrogen fluoride (HF), tetrafluoroboric acid (HBF₄), hexafluorosilicic acid (H₂SiF₆), hexafluorozirconic acid (H₂ZrF₆), hexafluorotitanic acid (H₂TiF₆), hexafluorophosphoric acid (HPF₆), hexafluoroaluminic acid (H₂AlF₆), hexafluorogermanic acid (H₂GeF₆), and salts thereof.

8. The method for producing a semiconductor substrate for memory elements according to claim 5, wherein the metallic tungsten corrosion inhibiter (C) contains at least one selected from the group consisting of ammonium salts represented by Formula (1) and heteroaryl salts having an alkyl group with 5 to 30 carbon atoms: 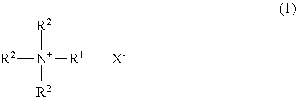
wherein in Formula (1),
R¹ represents an alkyl group with 5 to 30 carbon atoms, a substituted or unsubstituted alkyl(poly)heteroalkylene group, a substituted or unsubstituted aryl(poly)heteroalkylene group, or a group represented by Formula (2): 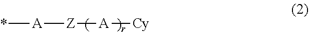
wherein in Formula (2),
Cy is a substituted or unsubstituted cycloalkyl group with 3 to 10 carbon atoms, a substituted or unsubstituted heterocycloalkyl group with 2 to 10 carbon atoms, a substituted or unsubstituted aryl group with 6 to 15 carbon atoms, or a substituted or unsubstituted heteroaryl group with 2 to 15 carbon atoms, each A independently represents an alkylene with 1 to 5 carbon atoms,
r is 0 or 1, and
Z is any of the following formulae: 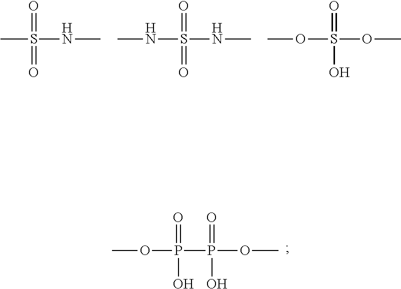
each R² independently represents a substituted or unsubstituted alkyl group with 1 to 18 carbon atoms, or a substituted or unsubstituted aryl group with 6 to 20 carbon atoms; and
X is a halide ion, a hydroxide ion, an organic sulfonate ion, tetrafluoroborate, or hexafluorophosphate.
